(19) United States
(12) Patent Application Publication
(10) Pub. No.: US 2026/0230060 A1
(43) Pub. Date: Aug. 6, 2026

(54) BULK ACOUSTIC WAVE FILTER AND METHOD FOR MANUFACTURING SAME

(71) Applicant: NITTO DENKO CORPORATION, Ibaraki-shi, Osaka (JP)

(72) Inventors: Takahiko YANAGITANI, Tokyo (JP); Satoshi TOKAI, Tokyo (JP)

(21) Appl. No.: 19/147,865

(22) PCT Filed: Jan. 23, 2024
(86) PCT No.: PCT/JP2024/001898

§ 371 Date: Jul. 14, 2025

(30) Foreign Application Priority Data
Jan. 24, 2023 (JP) 2023-008867
Aug. 30, 2023 (JP) 2023-140222

(51) Int. Cl. H03H 9/54; H03H 3/04; H03H 9/17

(52) U.S. Cl. CPC H03H 9/54; H03H 3/04; H03H 9/17; H03H 2003/0407

(57) ABSTRACT

A SMR-type BAW filter includes an acoustic Bragg reflector and a piezoelectric layer disposed on the acoustic Bragg reflector. The acoustic Bragg reflector includes first acoustic impedance layers and second acoustic impedance layers stacked alternately one by one. Each first acoustic impedance layer and each second acoustic impedance layer are formed of a polycrystalline or monocrystalline metal oriented in a predetermined direction. Acoustic impedance of each first acoustic impedance layer and acoustic impedance of each second acoustic impedance layer are different from each other. The piezoelectric layer is formed of a polycrystalline or monocrystalline piezoelectric material oriented in a predetermined direction. A crystal lattice of the polycrystalline or monocrystalline piezoelectric material is matched with a crystal lattice of the polycrystalline or monocrystalline metal of one layer among the first acoustic impedance layers and the second acoustic impedance layers, which is positioned in a vicinity of the piezoelectric layer.

### TECHNICAL FIELD

The present invention relates to bulk acoustic wave (BAW) filters that are frequency filters used in communication devices, such as smartphones, particularly solidly mounted resonator (SMR)-type BAW filters, and a method for manufacturing BAW filters.

### BACKGROUND ART

A BAW filter is a frequency filter that uses vibration of a bulk of a piezoelectric layer formed of a piezoelectric material to pass through a specific frequency band of an electric signal. As a frequency filter using a piezoelectric layer, a surface acoustic wave (SAW) filter, which utilizes surface acoustic waves (SAW) generated at a surface of a piezoelectric layer, is used. The BAW filter has characteristics that the BAW filter has a higher voltage resistance than the SAW filter, and can be used in a higher frequency band.

As BAW filters, there are SMR-type BAW filters, and film bulk acoustic resonator (FBAR)-type BAW filters. The SMR-type BAW filter includes a piezoelectric layer disposed on an acoustic Bragg reflector in which layers having mutually different acoustic impedances are alternately stacked. On the other hand, the FBAR-type BAW film includes a piezoelectric layer disposed on a top surface of a substrate having a part in which a cavity is formed. The top surface includes an upper portion of the cavity. Due to the above difference in structure, the SMR-type BAW filter has characteristics such that the SMR-type BAW filter has higher mechanical strength than the FBAR-type BAW filter.

Currently, an SMR-type BAW filter used as a frequency filter for a smartphone generally includes an acoustic Bragg reflector, in which low impedance layers formed of silicon dioxide (SiO₂) and high impedance layers formed of a metal that is an atom heavier than a constituent element of the low-impedance layers, such as tungsten (W), molybdenum (Mo), or the like, are stacked alternately one by one, and a piezoelectric layer formed of a piezoelectric material composed of microcrystals, in which a predetermined crystallographic axis is oriented in a direction perpendicular to the piezoelectric layer. In the coming future, frequency filter including a piezoelectric layer using a polycrystalline or monocrystalline piezoelectric material having high orientation precision will be desired for corresponding to a higher frequency band.

Patent Document 1 discloses that, on a surface of a substrate formed of monocrystalline silicon (Si), magnesium oxide (MgO), strontium titanate (SrTiO₃), or the like, two perovskite oxides having mutually different acoustic impedances, such as barium zirconate (BaZrO₃), magnesium barium tantalite (Ba(Mg_{1/3}Ta_{2/3})O₃), calcium titanate (CaTiO₃), and the like, are alternately stacked by epitaxy to form an acoustic Bragg reflector; and on a surface of the acoustic Bragg reflector, a piezoelectric layer formed of barium titanate is formed by epitaxy, thereby producing an SMR-type BAW filter. By forming the substrate, the acoustic Bragg reflector, and the piezoelectric layer in this order by epitaxy as described above, the piezoelectric layer has a polycrystalline or monocrystalline form that is matched with a crystal lattice of the crystals of the substrate and has high orientation precision. Thus, an SMR-type BAW filter corresponding to a high frequency band can be obtained.

### CITATION LIST

### Patent Document

Patent Document 1: Japanese Unexamined Patent Application Publication No. 2003-101375

### SUMMARY OF THE INVENTION

### Technical Problem

Since part of vibration energy is converted into heat in a piezoelectric layer, heat generated in the piezoelectric layer needs to be released outside an SMR-type BAW filter in order to prevent the increase in temperature of the SMR-type BAW filter. The acoustic Bragg reflector side of the SMR-type BAW filter is fixed to an external part so that the piezoelectric layer is allowed to vibrate as much as possible according to an input electric signal in a state in which the piezoelectric layer is not bound by the external part. Therefore, heat generated in the piezoelectric layer is dissipated to the external part through the acoustic Bragg reflector. However, the SMR-type BAW filter disclosed in Patent Document 1 has disadvantages such that heat conductivity is low and heat dissipation from the piezoelectric layer to the external part is low because the high impedance layers and the low impedance layers constituting the acoustic Bragg reflector are both formed of a ceramic.

The problem to be solved by the present invention is to provide an SMR-type BAW filter achieving high heat dissipation from a piezoelectric layer to an external part, while corresponding to a high frequency band.

### Solution to the Problem

A first SMR-type BAW filter according to the present invention accomplished for solving the above problem includes:
a) an acoustic Bragg reflector including first acoustic impedance layers and second acoustic impedance layers stacked alternately one by one,
   each first acoustic impedance layer and each second acoustic impedance layer being formed of a polycrystalline or monocrystalline metal oriented in a predetermined direction, and
   acoustic impedance of each first acoustic impedance layer and acoustic impedance of each second acoustic impedance layer being different from each other; and
b) a piezoelectric layer disposed on the acoustic Bragg reflector,
   the piezoelectric layer being formed of a polycrystalline or monocrystalline piezoelectric material oriented in a predetermined direction, and
   a crystal lattice of the polycrystalline or monocrystalline piezoelectric material being matched with a crystal lattice of the polycrystalline or monocrystalline metal of one layer among the first acoustic impedance layers and the second acoustic impedance layers, which is positioned in a vicinity of the piezoelectric layer.

Generally, metals have higher thermal conductivity than ceramics. As each of the layers constituting the acoustic Bragg reflector in the first SMR-type BAW filter according to the present invention is formed of a metal, all of the layers constituting the acoustic Bragg reflector have higher conductivity than an acoustic Bragg reflector formed of ceramics. Thus, the SMR-type BAW filter according to the present invention can improve heat dissipation performance from the piezoelectric layer to an external part via the acoustic Bragg reflector.

Moreover, the first SMR-type BAW filter according to the present invention can correspond to a high frequency band because the piezoelectric layer is formed of a polycrystalline or monocrystalline piezoelectric material oriented in a predetermined direction.

The SMR-type BAW filter having the above configuration can be easily manufactured by sequentially producing each of layers of an acoustic Bragg reflector and a piezoelectric layer by epitaxy. Specifically, a method for manufacturing the SMR-type BAW filter having the above configuration includes:
a substrate preparation step of preparing a monocrystalline substrate having a predetermined crystallographic plane at a surface of the monocrystalline substrate;
an acoustic Bragg reflector production step of forming first acoustic impedance layers and second acoustic impedance layers alternately one by one on the surface of the monocrystalline substrate by epitaxy to produce an acoustic Bragg reflector,
   each first acoustic impedance layer and each second acoustic impedance layer being formed of a metal having a crystal lattice matched with a crystal lattice of the monocrystalline substrate, and
   acoustic impedance of each first acoustic impedance layer and acoustic impedance of each second acoustic impedance layer being different from each other; and
a piezoelectric layer production step of producing a piezoelectric layer on the acoustic Bragg reflector by epitaxy,
   the piezoelectric layer being formed of a piezoelectric material having a crystal lattice matched with a crystal lattice of the metal of an uppermost layer among the first acoustic impedance layers and the second acoustic impedance layers.

The predetermined crystallographic plane of the substrate is determined according to the orientation direction of the polycrystalline form of the piezoelectric layer or the crystallographic axial direction of the monocrystalline form of the piezoelectric layer. For example, in the case where the piezoelectric layer formed of zinc oxide (ZnO), magnesium zinc oxide (MgZnO), aluminum nitride (AlN), scandium aluminum nitride (ScAlN) or the like having a hexagonal crystal lattice structure, is produced so that the (0001) plane is parallel to the piezoelectric layer, a monocrystalline material that has a crystallographic axis having 3-fold rotational symmetry or 6-fold rotational symmetry may be used as the substrate, and a plane perpendicular to the crystallographic axis may be determined as the predetermined crystallographic plane.

In the first SMR-type BAW filter according to the present invention, a value of a coefficient of thermal expansion of each first acoustic impedance layer and a value of a coefficient of thermal expansion of each second acoustic impedance layer are preferably close to each other. Specifically, an index value of a thermal expansion coefficient ratio, which is a value obtained by dividing a higher value by a lower value between the value of the coefficient of thermal expansion of each first acoustic impedance layer and the value of the coefficient of the thermal expansion of each second acoustic impedance layer, is preferably in the range of 1.0 to 1.1. Thus, a risk that either a first acoustic impedance layer or a second acoustic impedance layer is peeled off from the other by expansion or contraction due to a temperature change can be minimized.

For example, by using platinum (coefficient of linear expansion at room temperature: 8.8×10⁻⁶/K) as a material of either each first acoustic impedance layer or each second acoustic impedance layer and titanium (coefficient of linear expansion at room temperature: 8.4×10⁻⁶/K) as a material of the other, the index value of the coefficient of thermal expansion can be adjusted to 1.05.

An index value of an acoustic impedance ratio is preferably 3 or greater. The index value of the acoustic impedance ratio is a value obtained by dividing a higher value by a lower value between a value of the acoustic impedance of each first acoustic impedance layer and a value of the acoustic impedance of each second acoustic impedance layer. By using the first acoustic impedance layers and the second acoustic impedance layers having a large difference in acoustic impedance, acoustic Bragg reflection can occur even when the number of layers of the first acoustic impedance layers and the second acoustic impedance layers are reduced. The index value of the acoustic impedance ratio of the Bragg reflector disclosed in Patent Document 1 is 1.34, and it is necessary to provide 10 or more sets of a first acoustic impedance layer and a second acoustic impedance layer so that acoustic Bragg reflection occurs in the Bragg reflector disclosed in Patent Document 1. In contrast, when the index value of the acoustic impedance ratio is 3 or greater as in the present invention, the number of sets of the first acoustic impedance layer and the second acoustic impedance layer included in the acoustic Bragg reflector can be reduced to 6 sets or less.

For example, by using platinum (acoustic impedance of 85×10⁶) as a material of each first acoustic impedance layer or each second acoustic impedance layer and using titanium (acoustic impedance of 27×10⁶) as a material of the other, the index value of the acoustic impedance ratio can be set to 3.15. The SMR-type BAW filter using platinum for each first acoustic impedance layer or each second acoustic impedance layer and titanium for the other as described above is preferred in view of both the above-described coefficient of thermal expansion and the acoustic impedance ratio.

Note that another layer may be interposed between the acoustic Bragg reflector and the piezoelectric layer. For example, one of a pair of electrodes disposed to sandwich the piezoelectric layer may be interposed between the acoustic Bragg reflector and the piezoelectric layer. Generally, the above electrodes are formed of a metal, and therefore the electrodes are less likely to affect heat dissipation from the piezoelectric layer to the external part. Moreover, a buffer layer may be interposed between the acoustic Bragg reflector and the piezoelectric layer. The buffer layer is formed of a metal or an insulating material (piezoelectric material) matched with the crystal lattice of the polycrystalline or monocrystalline form of the piezoelectric layer, and matched with the crystal lattice of the polycrystalline or monocrystalline metal of one layer among the first acoustic impedance layers and the second acoustic impedance layers, which is positioned in the vicinity of the piezoelectric layer. By interposing the above buffer layer between the acoustic Bragg reflector and the piezoelectric layer, crystalline characteristics of the piezoelectric layer can be further improved. In the case where the buffer layer is formed of an insulating material, the buffer layer is desirably thin (for example, thinner than the piezoelectric layer) in order to minimize influence on heat dissipation from the piezoelectric layer to the external part as much as possible.

A second SMR-type BAW filter according to the present invention includes:
a) an acoustic Bragg reflector including first acoustic impedance layers and second acoustic impedance layers stacked alternately one by one,
   each first acoustic impedance layer formed of a polycrystalline or monocrystalline metal oriented in a predetermined direction, and
   each second acoustic impedance layer formed of a polycrystalline or monocrystalline ceramic oriented in a predetermined direction, and having acoustic impedance different from acoustic impedance of each first acoustic impedance layer; and
b) a piezoelectric layer disposed on the acoustic Bragg reflector,
   the piezoelectric layer being formed of a polycrystalline or monocrystalline piezoelectric material oriented in a predetermined direction, and
   a crystal lattice of the polycrystalline or monocrystalline piezoelectric material being matched with a crystal lattice of a polycrystalline or monocrystalline layer among the first acoustic impedance layers and the second acoustic impedance layer, which is positioned in a vicinity of the piezoelectric layer.

In the second SMR-type BAW filter according to the present invention, either each first acoustic impedance layer or each second acoustic impedance layer is formed of a metal. Thus, the second SMR-type BAW filter according to the present invention has better heat dissipation performance from the piezoelectric layer to the external part via the acoustic Bragg reflector than an SMR-type BAW filter including an acoustic Bragg reflector in which all layers are formed of ceramics. Moreover, the second SMR-type BAW filter according to the present invention can correspond to a high frequency band because the piezoelectric layer is formed of a polycrystalline or monocrystalline piezoelectric material oriented in a predetermined direction.

The present invention can have a configuration including:
two of the second SMR-type BAW filters arranged to be apart from each other in a direction parallel to the first acoustic impedance layers and the second acoustic impedance layers; and
a connecting member formed of a ceramic, via which the acoustic Bragg reflectors in the two of the SMR-type BAW filters are coupled to each other.

By (mechanically) connecting the couple (or three or more) of the second SMR-type BAW filters with the connecting member formed of a ceramic, a device in which multiple SMR-type BAW filter are integrated can be produced while electrically insulating the acoustic Bragg reflectors from one another. In this case, each second acoustic impedance layer and the connecting member can be simultaneously formed during the production of the device because the material of the connecting member and the material of each second acoustic impedance layer are the same (the ceramic). Thus, the production process can be simplified.

A method for manufacturing the second SMR-type BAW filter according to the present invention includes:
a substrate preparation step of preparing a monocrystalline substrate having a predetermined crystallographic plane at a surface of the monocrystalline substrate;
an acoustic Bragg reflector production step of forming first acoustic impedance layers and second acoustic impedance layers alternately one by one on the surface of the monocrystalline substrate by epitaxy to produce an acoustic Bragg reflector,
   each first acoustic impedance layer being formed of a polycrystalline or monocrystalline metal oriented in a predetermined direction,
   each second acoustic impedance layer being formed of a polycrystalline or monocrystalline ceramic oriented in a predetermined direction, and having acoustic impedance different from acoustic impedance of each first acoustic impedance layer; and
a piezoelectric layer production step of producing a piezoelectric layer on the acoustic Bragg reflector by epitaxy,
   the piezoelectric layer being formed of a piezoelectric material having a crystal lattice matched with a crystal lattice of an uppermost layer among the first acoustic impedance layers and the second acoustic impedance layers.

Note that the order of stacking the first acoustic impedance layers and the second acoustic impedance layers is not limited. Accordingly, the layer that is the closest to the surface of the substrate among layers constituting the acoustic Bragg reflector may be a first acoustic impedance layer (i.e., a layer formed of a metal) or a second acoustic impedance layer (a layer formed of a ceramic).

In the method for manufacturing the second SMR-type BAW filter,
the acoustic Bragg reflector production step can include:
when the first acoustic impedance layers and the second acoustic impedance layer are formed, producing two acoustic Bragg reflectors being apart from each other in a direction parallel to the first acoustic impedance layers and the second acoustic impedance layers; and
at the same time as the formation of each second acoustic impedance layer, allowing the polycrystalline or monocrystalline ceramic to grow between two of the second acoustic impedance layers and between two of the first acoustic impedance layers immediately below the two of the second acoustic impedance layers. Thus, a device in which the couple (or three or more) of the second SMR-type BAW filters are coupled to each other via the connecting member formed of a ceramic can be easily produced.

### Effects of the Invention

According to the present invention, an SMR-type BAW filter achieving high heat dissipation from a piezoelectric layer to an external part, while corresponding to a high frequency band, can be obtained.

### BRIEF DESCRIPTION OF THE DRAWINGS

FIG. 1 A vertical cross-sectional view illustrating a schematic configuration of one embodiment (first embodiment) of a first SMR-type BAW filter according to the present invention.

FIG. 2A A vertical cross-sectional view illustrating a substrate preparation step in a method for manufacturing an SMR-type BAW filter of a first embodiment.

FIG. 2B A vertical cross-sectional view illustrating interim progress of an acoustic Bragg reflector production step in the method for manufacturing the SMR-type BAW filter of the first embodiment.

FIG. 2C A vertical cross-sectional view illustrating the interim progress of the acoustic Bragg reflector production step in the method for manufacturing the SMR-type BAW filter of the first embodiment.

FIG. 2D A vertical cross-sectional view illustrating a state in which the acoustic Bragg reflector is produced in the method for manufacturing the SMR-type BAW filter of the first embodiment.

FIG. 2E A vertical cross-sectional view illustrating a state in which a first electrode layer is produced in the method for manufacturing the SMR-type BAW filter of the first embodiment.

FIG. 2F A vertical cross-sectional view illustrating a state in which a piezoelectric layer is produced in the method for manufacturing the SMR-type BAW filter of the first embodiment.

FIG. 3A A scanning electron micrograph capturing a vertical cross-section of the SMR-type BAW filter of the first embodiment in which the piezoelectric layer is formed of zinc oxide.

FIG. 3B A scanning electron micrograph capturing a vertical cross-section of the SMR-type BAW filter of the first embodiment in which the piezoelectric layer is formed of magnesium zinc oxide.

FIG. 3C A scanning electron micrograph capturing a vertical cross-section of the SMR-type BAW filter of the first embodiment in which the piezoelectric layer is formed of scandium aluminum nitride.

FIG. 4A A graph depicting a result of ray diffraction analysis of the SMR-type BAW filter of the first embodiment, in which the piezoelectric layer is formed of zinc oxide, performed by a 2θ-ω scan.

FIG. 4B A graph depicting a result of X-ray diffraction analysis of the SMR-type BAW filter of the first embodiment, in which the piezoelectric layer is formed of magnesium zinc oxide, performed by a 2θ-ω scan.

FIG. 4C A graph depicting a result of X-ray diffraction analysis of the SMR-type BAW filter of the first embodiment, in which the piezoelectric layer is formed of scandium aluminum nitride, performed by a 2θ-ω scan.

FIG. 5A A (002) pole figure of a first acoustic impedance layer of the SMR-type BAW filter of the first embodiment obtained by X-ray diffraction analysis.

FIG. 5B A (10-12) pole figure of a second acoustic impedance layer of the SMR-type BAW filter of the first embodiment obtained by X-ray diffraction analysis.

FIG. 5C A (10-11) pole figure of the piezoelectric layer, which is formed of zinc oxide, of the SMR-type BAW filter of the first embodiment obtained by X-ray diffraction analysis.

FIG. 5D A (10-11) pole figure of the piezoelectric layer, which is formed of magnesium zinc oxide, of the SMR-type BAW filter of the first embodiment obtained by X-ray diffraction analysis.

FIG. 5E A (10-11) pole figure of the piezoelectric layer, which is formed of scandium aluminum nitride, of the SMR-type BAW filter of the first embodiment obtained by X-ray diffraction analysis.

FIG. 6A An electron diffraction image of the piezoelectric layer, which is formed of zinc oxide, of the first embodiment of the SMR-type BAW filter.

FIG. 6B An electron diffraction image of the piezoelectric layer, which is formed of scandium aluminum nitride, of the SMR-type BAW filter of the first embodiment.

FIG. 7A A graph depicting a measurement result of frequency response of the SMR-type BAW filter of the first embodiment, in which the piezoelectric layer is formed of zinc oxide.

FIG. 7B A graph depicting a measurement result of frequency response of the SMR-type BAW filter of the first embodiment, in which the piezoelectric layer is formed of magnesium zinc oxide.

FIG. 7C A graph depicting a measurement result of frequency response of the SMR-type BAW filter of the first embodiment, in which the piezoelectric layer is formed of scandium aluminum nitride.

FIG. 8 A vertical cross-sectional view illustrating a schematic configuration of a modified example of the SMR-type BAW filter of the first embodiment.

FIG. 9A A scanning electron micrograph capturing a vertical cross-section of one example of the SMR-type BAW filter of the first embodiment, in which the piezoelectric layer formed of scandium aluminum nitride (Sc_{0.12}Al_{0.88}N) is produced without heating.

FIG. 9B A scanning electron micrograph capturing a vertical cross-section of one example of the SMR-type BAW filter of the first embodiment, in which the piezoelectric layer formed of scandium aluminum nitride (Sc_{0.40}Al_{0.60}N) is produced without heating.

FIG. 10A A graph depicting a result of X-ray diffraction analysis of one example of the SMR-type BAW filter, in which the piezoelectric layer formed of Sc_{0.12}Al_{0.88}N is produced without heating, by a 2θ-ω scan.

FIG. 10B A graph depicting a result of X-ray diffraction analysis of one example of the SMR-type BAW filter, in which the piezoelectric layer formed of Sc_{0.40}Al_{0.60}N is produced without heating, by a 2θ-ω scan.

FIG. 11A A (10-11) pole figure of one example of a first embodiment of the SMR-type BAW filter, in which the piezoelectric layer formed of Sc_{0.12}Al_{0.88}N is produced without heating, obtained by X-ray diffraction analysis.

FIG. 11B A (10-11) pole figure of one example of a first embodiment of the SMR-type BAW filter, in which the piezoelectric layer formed of Sc_{0.40}Al_{0.60}N is produced without heating, obtained by X-ray diffraction analysis.

FIG. 12 An electron diffraction image of one example of the first embodiment of the SMR-type BAW filter, in which the piezoelectric layer formed of Sc_{0.12}Al_{0.88}N is produced without heating.

FIG. 13 A graph depicting a result of X-ray diffraction analysis of one example of the first embodiment of the SMR-type BAW filter, in which the piezoelectric layer formed of Sc_{0.12}Al_{0.88}N is produced without heating, by an ω scan.

FIG. 14 A graph depicting a result of X-ray diffraction analysis of one example of the first embodiment of the SMR-type BAW filter, in which the piezoelectric layer formed of Sc_{0.12}Al_{0.88}N is produced without heating, by a φ scan on the (10-11) plane.

FIG. 15A A graph depicting a measurement result of acoustic impedance of one example of the first embodiment of the SMR-type BAW filter, in which the piezoelectric layer formed of Sc_{0.12}Al_{0.88}N is produced without heating.

FIG. 15B A graph depicting a measurement result of acoustic impedance of one example of the first embodiment of the SMR-type BAW filter, in which the piezoelectric layer formed of Sc_{0.40}Al_{0.60}N is produced without heating.

FIG. 16A A graph depicting a determination result of a real part of acoustic impedance of one example of the first embodiment of the SMR-type BAW filter, in which the piezoelectric layer formed of Sc_{0.12}Al_{0.88}N is produced without heating.

FIG. 16B A graph depicting a determination result of a real part of acoustic impedance of one example of the first embodiment of the SMR-type BAW filter, in which the piezoelectric layer formed of Sc_{0.40}Al_{0.60}N is produced without heating.

FIG. 17 A vertical cross-sectional view illustrating a schematic configuration of one embodiment (second embodiment) of a second SMR-type BAW filter according to the present invention.

FIG. 18 A vertical cross-sectional view illustrating a schematic configuration of a multi-integrated device in which two or more SMR-type BAW filters of the second embodiment are combined.

FIG. 19A A vertical cross-sectional view illustrating a production process of a multi-integrated device.

FIG. 19B A vertical cross-sectional view illustrating the production process of the multi-integrated device.

FIG. 19C A vertical cross-sectional view illustrating the production process of the multi-integrated device.

FIG. 19D A vertical cross-sectional view illustrating the production process of the multi-integrated device.

FIG. 20A A scanning electron micrograph capturing a vertical cross-section of the SMR-type BAW filter of the second embodiment in which the piezoelectric layer is formed of zinc oxide.

FIG. 20B A scanning electron micrograph capturing a vertical cross-section of the SMR-type BAW filter of the second embodiment in which the piezoelectric layer is formed of magnesium zinc oxide.

FIG. 20C A scanning electron micrograph capturing a vertical cross-section of the SMR-type BAW filter of the second embodiment in which the piezoelectric layer is formed of scandium aluminum nitride.

FIG. 21A A graph depicting a result of X-ray diffraction analysis of the SMR-type BAW filter of the second embodiment, in which the piezoelectric layer is formed of zinc oxide, performed by a 2θ-ω scan.

FIG. 21B A graph depicting a result of X-ray diffraction analysis of the SMR-type BAW filter of the second embodiment, in which the piezoelectric layer is formed of magnesium zinc oxide, performed by a 2θ-ω scan.

FIG. 21C A graph depicting a result of X-ray diffraction analysis of the SMR-type BAW filter of the second embodiment, in which the piezoelectric layer is formed of scandium aluminum nitride, performed by a 2θ-ω scan.

FIG. 22A A graph depicting a result of X-ray diffraction analysis of the SMR-type BAW filter of the second embodiment, in which the piezoelectric layer is formed of zinc oxide, performed by an ω scan.

FIG. 22B A graph depicting a result of X-ray diffraction analysis of the SMR-type BAW filter of the second embodiment, in which the piezoelectric layer is formed of magnesium zinc oxide, performed by an ω scan.

FIG. 22C A graph depicting a result of X ray diffraction analysis of the SMR-type BAW filter of the second embodiment, in which the piezoelectric layer is formed of scandium aluminum nitride, performed by an ω scan.

FIG. 23A A graph depicting a result of X-ray diffraction analysis of the SMR-type BAW filter of the second embodiment, in which the piezoelectric layer is formed of zinc oxide, performed by a φ scan on the (10-11) plane.

FIG. 23B A graph depicting a result of X-ray diffraction analysis of the SMR-type BAW filter of the second embodiment, in which the piezoelectric layer is formed of magnesium zinc oxide, by a φ scan on the (10-11) plane.

FIG. 23C A graph depicting a result of X-ray diffraction analysis of the SMR-type BAW filter of the second embodiment, in which the piezoelectric layer is formed of scandium aluminum nitride, by a φ scan on the (10-11) plane.

FIG. 24A A (10-11) pole figure of the piezoelectric layer, which is formed of zinc oxide, of the SMR-type BAW filter of the second embodiment obtained by X-ray diffraction analysis.

FIG. 24B A (10-11) pole figure of the piezoelectric layer, which is formed of magnesium zinc oxide, of the SMR-type BAW filter of the second embodiment obtained by X-ray diffraction analysis.

FIG. 24C A (10-11) pole figure of the piezoelectric layer, which is formed of scandium aluminum nitride, of the SMR-type BAW filter of the second embodiment obtained by X-ray diffraction analysis.

FIG. 25 A graph depicting a measurement result of acoustic impedance of the SMR-type BAW filter of the second embodiment in which the piezoelectric layer is formed of scandium aluminum nitride.

FIG. 26 A graph depicting a determination result of a real part of acoustic impedance of the SMR-type BAW filter of the second embodiment in which the piezoelectric layer is formed of scandium aluminum nitride.

### DETAILED DESCRIPTION OF THE EMBODIMENTS

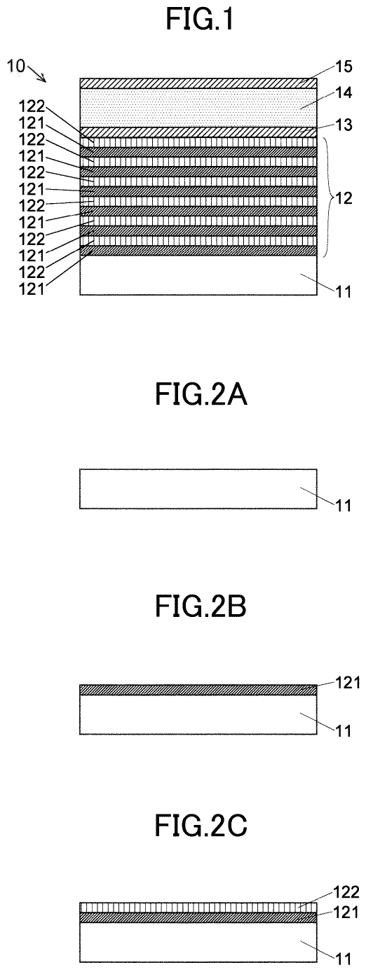

Embodiments of an SMR-type BAW filter and a method for manufacturing an SMR-type BAW filter according to the present invention will be described with reference to FIGS. 1 to 26.

### (1) Configuration of SMR-Type BAW Filter of First Embodiment

FIG. 1 presents a vertical cross-sectional view of a schematic configuration of an SMR-type BAW filter 10 that is one embodiment (first embodiment) of a first SMR-type BAW filter. As illustrated in FIG. 1, the SMR-type BAW filter 10 has a structure in which a substrate 11, an acoustic Bragg reflector 12, a first electrode layer 13, a piezoelectric layer 14, and a second electrode layer 15 are stacked in this order.

The substrate 11 is used for producing the SMR-type BAW filter 10 and is not an essential constituent component of the SMR-type BAW filter 10, thus the substrate 11 is not necessarily provided. However, the substrate 11 does not adversely affect operation of the SMR-type BAW filter 10, and has a secondary function of supporting the SMR-type BAW filter 10. Therefore, the substrate 11 is allowed to remain in the SMR-type BAW filter as it is in the present embodiment. In the present embodiment, as the substrate 11, a monocrystalline sapphire having a hexagonal crystal lattice structure is used. The monocrystalline sapphire is cut out so that the (0001) plane of the crystal is exposed at the surface of the substrate 11. Instead of sapphire, a monocrystalline material, such as silicon carbide (Sic), silicon (Si), magnesium oxide (MgO), strontium titanate (SrTiO₃), gallium arsenide (GaAs), germanium (Ge), or the like, may be used as the material of the substrate 11.

The acoustic Bragg reflector 12 has a structure in which first acoustic impedance layers 121 and second acoustic impedance layers 122, which are formed of mutually different materials, are stacked alternately one by one. In FIG. 1, six first acoustic impedance layers 121 and six second acoustic impedance layer 122 are disposed, but the number of layers is not limited to 6 layers each, as long as two layers or more are provided for each. Each first acoustic impedance layer 121 and each second acoustic impedance layers 122 are both formed of a metal. Since both each first acoustic impedance layer 121 and each second acoustic impedance layer 122 are produced by epitaxy as described later, the first acoustic impedance layers 121 and the second acoustic impedance layers 122 are in an oriented polycrystalline or monocrystalline form.

In the present embodiment, a layer formed of platinum (Pt) is used as each first acoustic impedance layer 121, and a layer formed of titanium (Ti) is used as each second acoustic impedance layer 122. Since atoms of titanium are lighter than atoms of platinum, each second acoustic impedance layer 122 has lower acoustic impedance than each first acoustic impedance layer 121. Specifically, the acoustic impedance of each first acoustic impedance layer 121 is 85×10⁶, and the acoustic impedance of each second acoustic impedance layer 122 is 27×10⁶. Thus, an index value of the acoustic impedance ratio is a high value, that is, 3.15. Therefore, acoustic Bragg reflection can be achieved by disposing six first acoustic impedance layers 121 and six second acoustic impedance layers 122. Moreover, coefficients of thermal expansion of platinum and titanium are close to each other (at room temperature, a coefficient of thermal expansion of platinum being 8.8×10⁻⁶/K, a coefficient of thermal expansion of titanium being 8.4×10⁻⁶/K). As a result, the coefficient of thermal expansion of each first acoustic impedance layer 121 and the coefficient of thermal expansion of each second acoustic impedance layer 122 are close to each other (index value of thermal expansion coefficient ratio is 1.05). Thus, a risk that either a first acoustic impedance layer 121 or a second acoustic impedance layer 122 is peeled off from the other by expansion or contraction due to a temperature change can be minimized.

Materials for each first acoustic impedance layer 121 and each second acoustic impedance layer 122 are not limited to the above example. As the material of each first acoustic impedance layer 121, for example, a single substance or an alloy of molybdenum (Mo), tantalum (Ta), hafnium (Hf), iridium (Ir), ruthenium (Ru), tungsten (W), gold (Au), zirconium (Zr), niobium (Nb), or the like can be used, other than platinum. As a material of each second acoustic impedance layer 122, for example, a single substance or an alloy of scandium (Sc), vanadium (V), chromium (Cr), manganese (Mn), iron (Fe), cobalt (Co), nickel (Ni), copper (Cu), zinc (Zn), germanium (Ge), aluminum (Al), silicon (Si), carbon (C), or the like, can be used, other than titanium. Note that graphene having metallic thermal conductivity is used as a single substance of carbon (C). Atoms that are elements of the above-listed materials of each second acoustic impedance layer 122 are all lighter than atoms that are elements of the above-listed materials of each first acoustic impedance layer 121.

The first electrode layer 13 is not particularly limited, as long as the first electrode layer 13 is a layer formed of a material having conductivity. In the present embodiment, the first electrode layer 13 is produced by epitaxy as described later, and therefore the first electrode layer 13 is in an oriented polycrystalline or monocrystalline form. In the present embodiment, a material of the electrode is platinum. In the case where the acoustic Bragg reflector 12 has sufficiently high conductivity as an electrode, the first electrode layer 13 may be omitted, and the acoustic Bragg reflector 12 may be used as an electrode.

The piezoelectric layer 14 is formed of a polycrystalline or monocrystalline piezoelectric material oriented in a predetermined direction. In the present embodiments, three types of SMR-type BAW filters 10, in which a piezoelectric layer 14 is monocrystalline zinc oxide (ZnO), monocrystalline magnesium zinc oxide (MgZnO), and monocrystalline scandium aluminum nitride (ScAlN), respectively, are produced. The above three materials all have a wurtzite structure that is a hexagonal crystal. Moreover, all of the above three types of piezoelectric layers 14 are produced by epitaxy as described later, and the c axis is arranged to be perpendicular to the corresponding piezoelectric layer 14. The crystallographic plane (0001) of the hexagonal crystal is appeared at the both top and bottom surfaces of the piezoelectric layer 14, and atoms are oriented to have 6-fold rotational symmetry with respect to a c-axis at the surfaces. The material of the piezoelectric layer 14 is not limited to the above three examples, and another piezoelectric material, such as aluminum nitride (AlN) or the like, may be used.

The second electrode layer 15 is not particularly limited, as long as the second electrode layer 15 is a layer formed of a material having conductivity. In the present embodiment, the second electrode layer 15 formed of gold is used. The second electrode layer 15 is not necessarily in an oriented polycrystalline or monocrystalline form, and is not necessarily formed by epitaxy.

### (2) Method for Manufacturing SMR-Type BAW Filter of Present Embodiment

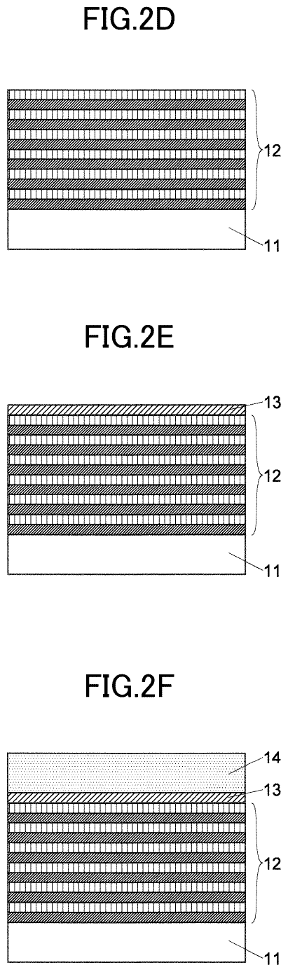

The SMR-type BAW filter 10 of the present embodiment is produced by the method illustrated in FIGS. 2A to 2F. First, a substrate 11 formed of monocrystalline sapphire cut out to expose the (0001) plane of the crystal at a surface is prepared (FIG. 2A: substrate preparation step). Such a substrate is commercially available on the market, and therefore such a commercially available product may be used as the substrate 11 as it is.

Hereinafter, an acoustic Bragg reflector 12 (FIGS. 2B to 2D: acoustic Bragg reflector production step), a first electrode layer 13 (FIG. 2E), and a piezoelectric layer 14 (FIG. 2F) are produced in this order on the substrate 11 by epitaxy (FIGS. 2B to 2F). In the present embodiment, a radio frequency (RF) magnetron sputtering device is used for production of all of the above layers. During the production of the acoustic Bragg reflector 12, the following process is repeatedly performed. That is, first, one layer of the first acoustic impedance layer 121 is produced on the substrate 11 (FIG. 2B), one layer of the second acoustic impedance layer 122 is formed on the produced first acoustic impedance layer 121 (FIG. 2C), and the first acoustic impedance layer 121 is produced on the produced second acoustic impedance layer 122.

Conditions associated with the RF magnetron sputtering device when each layer is produced are as follows.

### First Acoustic Impedance Layer 121

A target formed of platinum is placed on a cathode of the RF magnetron sputtering device, a surface of a substrate 11 or a surface of a second acoustic impedance layer 122, to which a first acoustic impedance layer 121 is produced, is arranged to face the target in a position 30 mm away from the target. In an argon gas atmosphere at a pressure of 0.5 Pa, film formation is performed for 10 minutes per layer at a temperature of 500° C., while applying a radio-frequency powder of 80 W, until a thickness of a forming layer reaches 450 nm.

### Second Acoustic Impedance Layer 122

A target formed of titanium is placed on a cathode of the RF magnetron sputtering device, the surface of the first acoustic impedance layer 121 to which a second acoustic impedance layer 122 is produced to face the target in a position 30 mm away from the target. In an argon gas atmosphere at a pressure of 0.5 Pa, film formation is performed for 30 minutes per layer at a temperature of 350° C., while applying a radio-frequency powder of 100 W, until a thickness of a forming layer reaches 760 nm.

### First Electrode Layer 13

A target formed of platinum is placed on a cathode of the RF magnetron sputtering device, and the surface of the second acoustic impedance layer 122 to which a first electrode layer 13 is produced is arranged to face the target in the position 30 mm away from the target. In an argon gas atmosphere at a pressure of 0.5 Pa, film formation is performed for 2 minutes per layer at a temperature of 500° C., while applying a radio-frequency powder of 80 W, until a thickness of a forming layer reaches 150 nm.

### Piezoelectric Layer 14

In the case where a piezoelectric layer 14 is formed of zinc oxide, a target formed of zinc oxide is placed on a cathode of the RF magnetron sputtering device, and the surface of the first electrode layer 13 is arranged to face the target in the position 30 mm away from the target. In a argon and oxygen gas mixture (a partial pressure ratio being 1 of oxygen to 3 of argon) atmosphere at a pressure of 1 Pa, film formation is performed for 30 minutes per layer at a temperature of 500° C., while applying a radio-frequency powder of 150 W, until a thickness of a forming layer reaches 1.2 μm.

In the case where a piezoelectric layer 14 is formed of magnesium zinc oxide, using a target formed of magnesium zinc oxide in the same armament conditions to the case of zinc oxide, in a argon and oxygen gas mixture (the same partial pressure ratio as above) atmosphere at a pressure of 1 Pa, film formation is performed for 40 minutes per layer at a temperature of 450° C., while applying a radio-frequency powder of 80 W, until a thickness of a forming layer reaches 1.0 μm.

In the case where a piezoelectric layer 14 is formed of scandium aluminum nitride, using a target formed of scandium aluminum nitride in the same arrangement conditions to the case of zinc oxide, in a argon and oxygen gas mixture (a partial pressure ratio being 1 of oxygen to 4 of argon) atmosphere at a pressure of 0.5 Pa, film formation is performed for 60 minutes per layer at a temperature of 450° C., while applying a radio-frequency powder of 100 W, until a thickness of a forming layer reaches 2.1 μm.

Since the acoustic Bragg reflector 12, the first electrode layer 13, and the piezoelectric layer 14 are all produced by epitaxy as described above, all layers in the acoustic Bragg reflector 12 and the first electrode layer 13 are formed in a polycrystalline or monocrystalline form oriented to match a crystalline lattice of the monocrystalline substrate 11, and the piezoelectric layer 14 is formed in a polycrystalline or monocrystalline form that is oriented to match with the crystal lattice of all layers of the acoustic Bragg reflector 12 and the first electrode layer 13.

By producing a second electrode layer 15 on the piezoelectric layer 14 after the production of the piezoelectric layer 14, production of an SMR-type BAW filter 10 is completed. The second electrode layer 15 is not necessarily produced by epitaxy as described above, and may be produced by a typical vapor deposition method or the like.

### (3) Measurement Results of SMR-Type BAW Filter of First Embodiment

Next, results of various measurements performed on the actually produced SMR-type BAW filter 10 of the first embodiment will be described. Note that, in an example in which the piezoelectric layer 14 was magnesium zinc oxide, the atomic ratio of magnesium to zinc was 3:7 (Mg_{0.3}Zn_{0.7}O). In the example in which the piezoelectric layer 14 was scandium aluminum nitride, the atomic ratio of scandium to aluminum was 12:88 (Sc_{0.12}Al_{0.88}N).

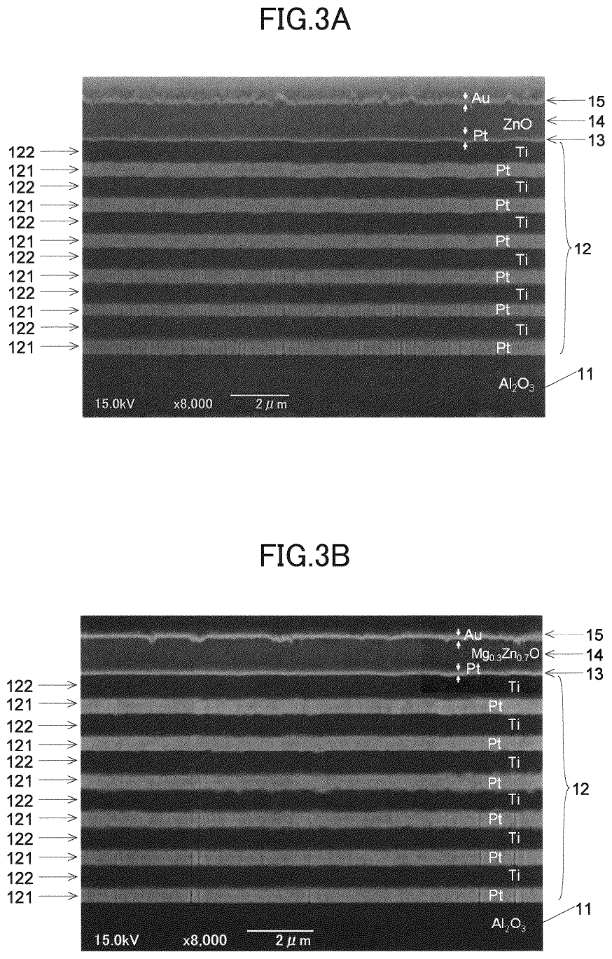

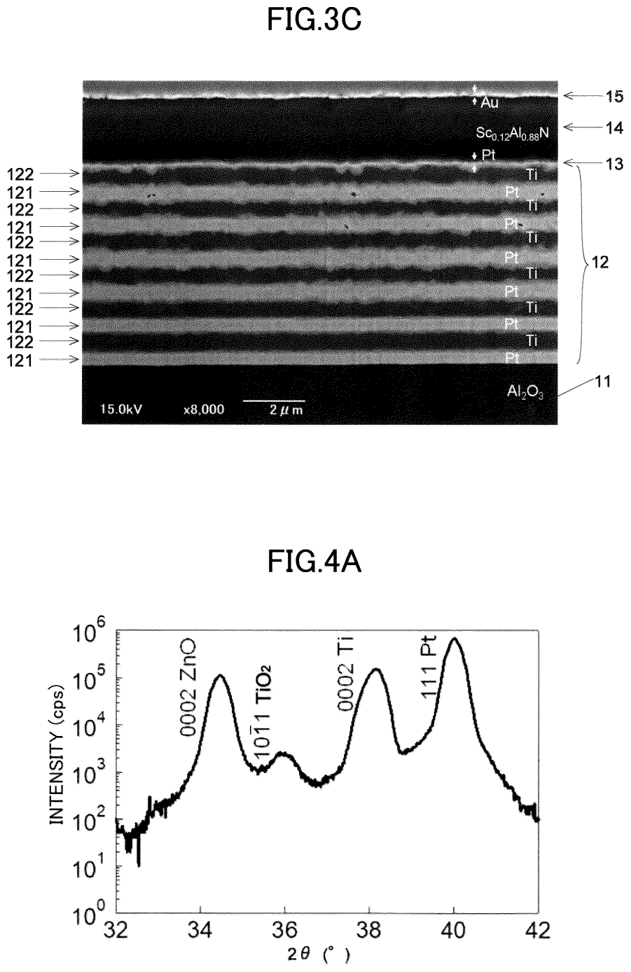

Scanning electron microscopic (SEM) photographs of vertical cross-sections of the produced SMR-type BAW filters 10 are presented in FIGS. 3A to 3C. NO column structure was observed in the piezoelectric layer 14 in all of the cases where the piezoelectric layer 14 was zinc oxide (FIG. 3A), magnesium zinc oxide (FIG. 3B), and scandium aluminum nitride (FIG. 3C).

Next, results obtained by X-ray diffraction analysis performed in a state in which the second electrode layer 15 was absent (before production of the second electrode layer 15), and the piezoelectric layer 14 was exposed to the surface are presented. First, a 2θ-ω scan was performed by varying ω and 2θ, while maintaining ω=θ, where ω was an incident angle of an incident X ray on the surface of the piezoelectric layer 14, and 2θ was an angle between the incident X ray and an output X ray detected by a detector.

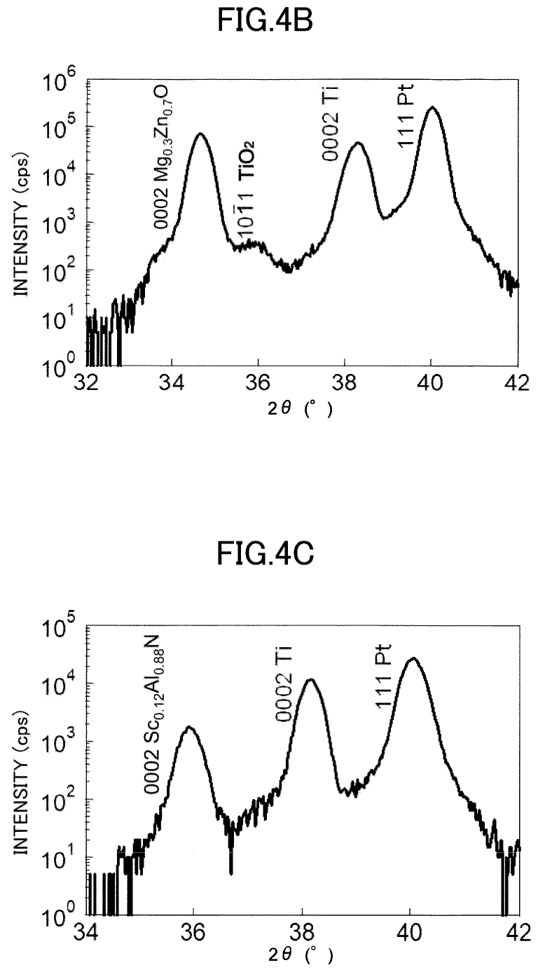

As a result, a diffraction peak attributed to the (0002) plane of the corresponding crystal was observed in all of the cases where the piezoelectric layer 14 was zinc oxide (FIG. 4A), magnesium zinc oxide (FIG. 4B), and scandium aluminum nitride (FIG. 4C). Moreover, in all of the cases, diffraction peaks attributed to the (0002) plane of the Ti crystal that was a hexagonal crystal, and the (111) plane of the Pt crystal having a face-centered cubic structure (cubic crystal system) were also observed in combination. Note that the (111) plane of the crystal having the face-centered cubic structure has 6-fold rotational symmetry similar to the (0002) plane of the hexagonal crystal. The above measurement results indicate that a crystal structure of the piezoelectric layer 14 is formed so as to follow the crystal structure of the substrate 11 via the acoustic Bragg reflector 12 and the first electrode layer 13 produced by epitaxy. In FIGS. 4A and 4B, a weak peak is observed around 36.0° other than the above three peaks. However, the above weak peak is assumed to be a diffraction peak attributed to the (10-11) plane of rutile TiO₂ formed in a small amount as a result of partial oxidation of titanium, and is not intrinsic.

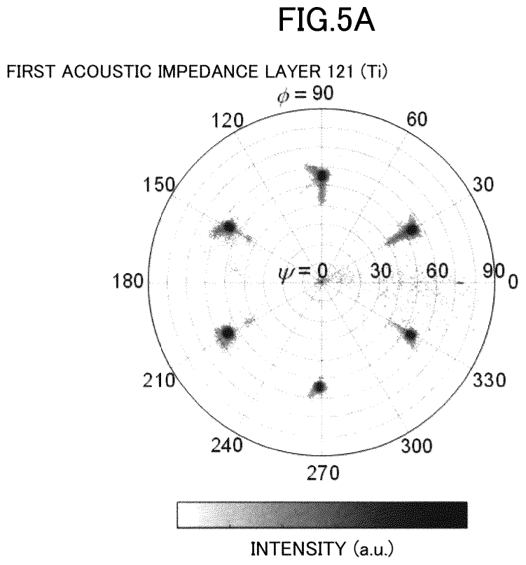

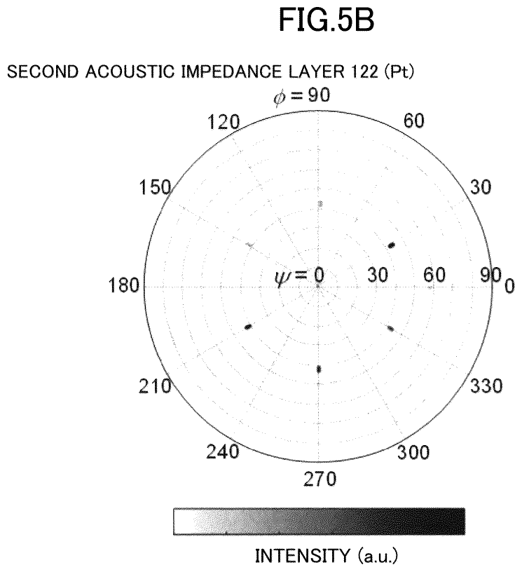

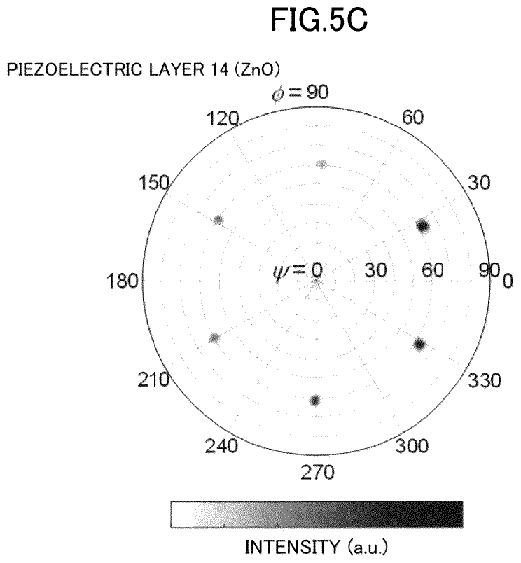

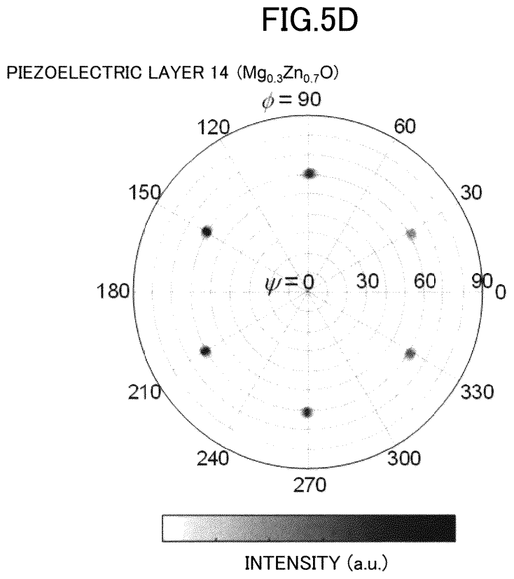

Next, the results of pole figure measurement performed on the first acoustic impedance layer 121, the second acoustic impedance layer 122, and the piezoelectric layer 14 will be described. In both the measurement of the first acoustic impedance layer 121 (FIG. 5A) and the measurement of the second acoustic impedance layer 122 (FIG. 5B), an intensity distribution having 6-fold rotational symmetry with respect to an axis perpendicular to a corresponding layer (azimuth angle φ) was obtained. In all of the measurement of the piezoelectric layer 14 formed of zinc oxide (FIG. 5C), the measurement of the piezoelectric layer 14 formed of magnesium zinc oxide (FIG. 5D), and the measurement of the piezoelectric layer 14 formed of scandium aluminum nitride (FIG. 5E), an intensity distribution having 6-fold rotational symmetry with respect to the axis perpendicular to a corresponding layer was obtained. The above results indicate that the first acoustic impedance layer 121 and the second acoustic impedance layer 122 were formed by following the 6-fold rotational symmetry of the crystal structure of the substrate 11, and the piezoelectric layer 14 was also formed by following the 6-fold rotational symmetry of the above layers.

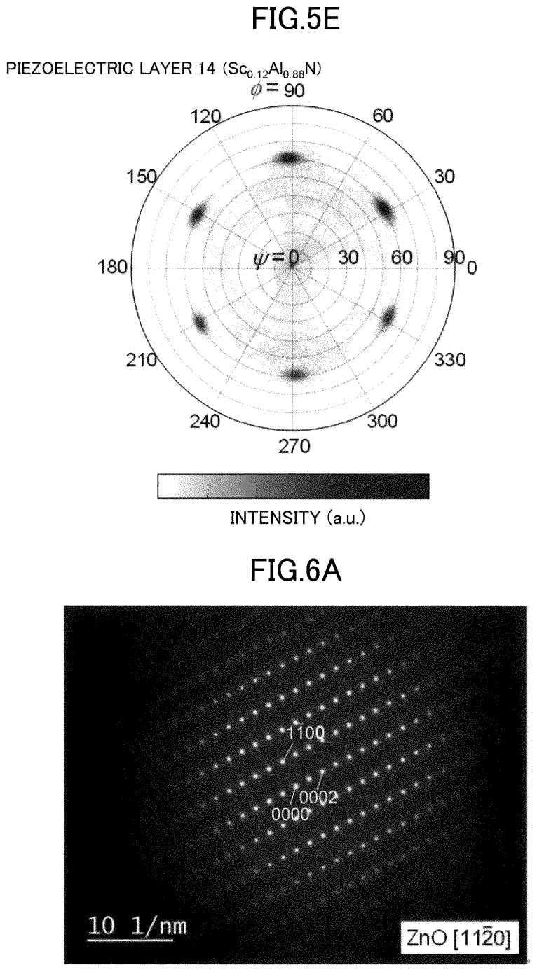

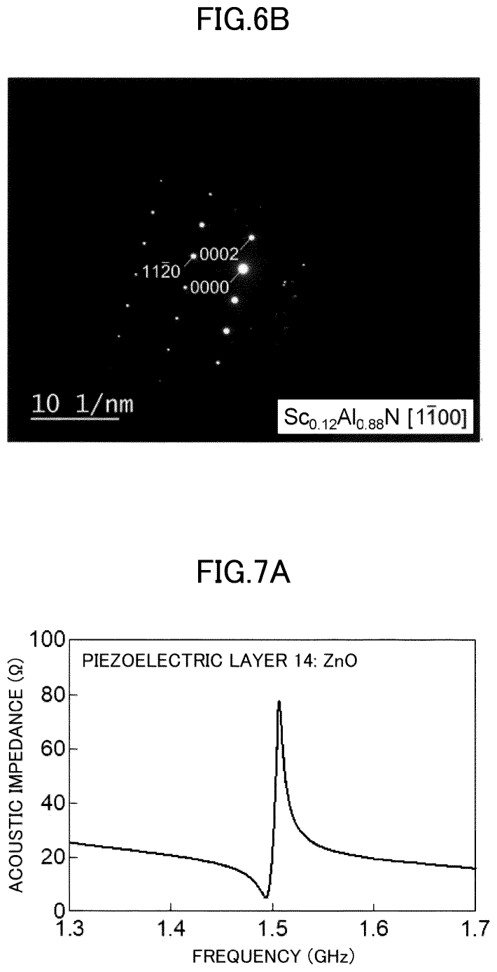

Further, the results of electron diffraction images obtained from the piezoelectric layer formed of zinc oxide and the piezoelectric layer formed of scandium aluminum nitride, respectively, will be described. From the piezoelectric layer formed of zinc oxide (FIG. 6A), the electron diffraction image including only clear diffraction spots corresponding to the predetermined crystallographic planes of the monocrystalline form (e.g., the (0000) plane, the (0002) plane, the (1100) plane, and the like) was obtained. It is therefore assumed that monocrystalline zinc oxide or polycrystalline zinc oxide close to the monocrystalline form (also having in-plane orientation in the same direction) was formed. From the piezoelectric layer formed of scandium aluminum nitride (FIG. 6B), the electron diffraction image, in which dark spots were observed in addition to clear diffraction spots corresponding to the predetermined crystallographic planes of the monocrystalline form, was obtained. It is therefore considered that the polycrystalline form, in which there was a portion oriented in a different direction to the orientation of the entire portion, was formed.

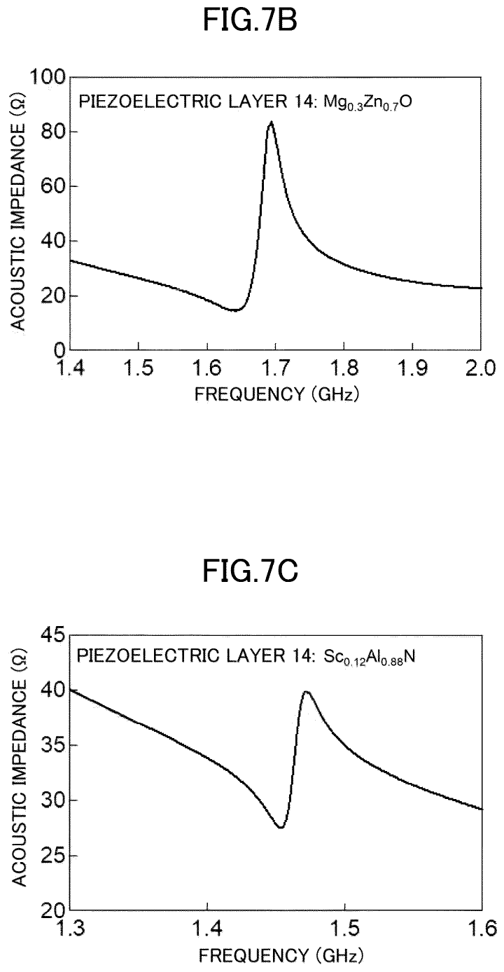

Next, the results of frequency response measured on the produced SMR-type BAW filters 10 will be described. In the case where the piezoelectric layer 14 was formed of zinc oxide (FIG. 7A), a peak was observed in the vicinity of the frequency of 1.5 GHz. In the case where the piezoelectric layer 14 was formed of magnesium zinc oxide (FIG. 7B), a peak was observed in the vicinity of the frequency of 1.6 GHz to 1.7 GHz. In the case where the piezoelectric layer 14 was formed of scandium aluminum nitride (FIG. 7C), a peak was observed in the vicinity of the frequency of 1.4 GHz to 1.5 GHz. It was confirmed that the piezoelectric layers 14 resonated at the above frequencies.

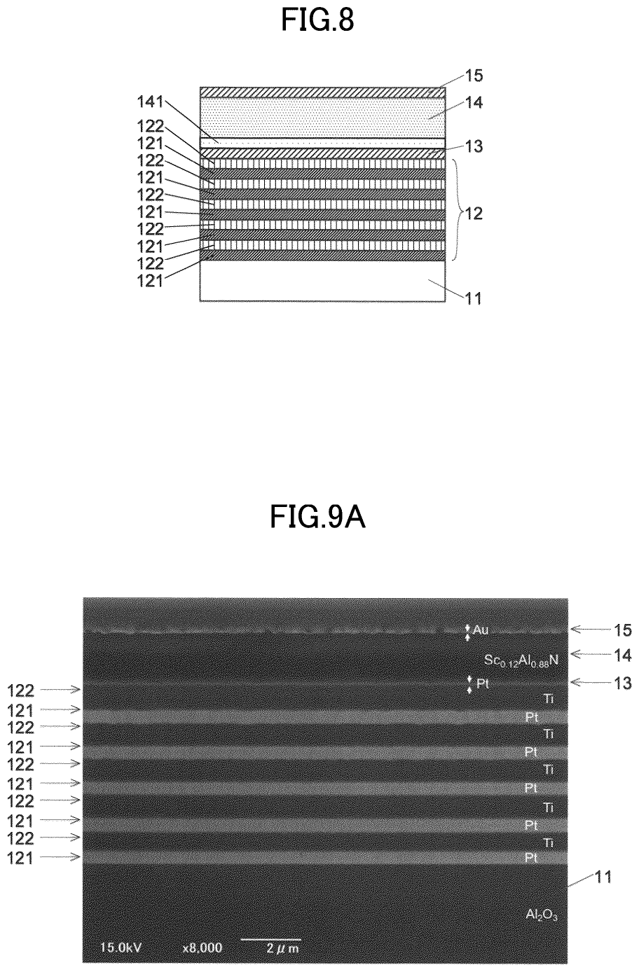

In the examples explained above, the piezoelectric layer 14 was produced in a heated state. An example in which a piezoelectric layer 14 was produced without heating by a heater in the case where the piezoelectric layer 14 was formed of scandium aluminum nitride will be described hereinafter. The piezoelectric layer 14 was produced with the atomic ratio of scandium to aluminum being (i) 12:88 (Sc_{0.12}Al_{0.88}N) that was the same as above, and (ii) 4:6 (Sc_{0.40}Al_{0.60}N) having the larger scandium ratio than the above. In the case of (ii), a buffer layer 141 formed of Sc_{0.12}Al_{0.88}N (see FIG. 8) was produced on the first electrode layer 13, and a piezoelectric layer 14 formed of Sc_{0.40}Al_{0.60}N was produced on the buffer layer 141. The production conditions of the piezoelectric layer 14 other than a temperature were set such that a gas atmosphere was an argon and nitrogen gas mixture at a pressure of 0.5 Pa, the applied radio-frequency power was set at 100 W, and film formation was performed until a thickness of a forming film reached 1.6 μm. The production conditions other than the production conditions of the piezoelectric layer 14 were the same as in the above examples, except that the number of layers of the first acoustic impedance layers 121 in the acoustic Bragg reflector 12 and the number of layers of the second acoustic impedance layers 122 in the acoustic Bragg reflector 12 were both 5 layers. Note that production of a piezoelectric layer 14 having the structure of (ii) was separately attempted, while heating at 450° C. In this case, the piezoelectric layer 14 formed through epitaxial growth could not be obtained.

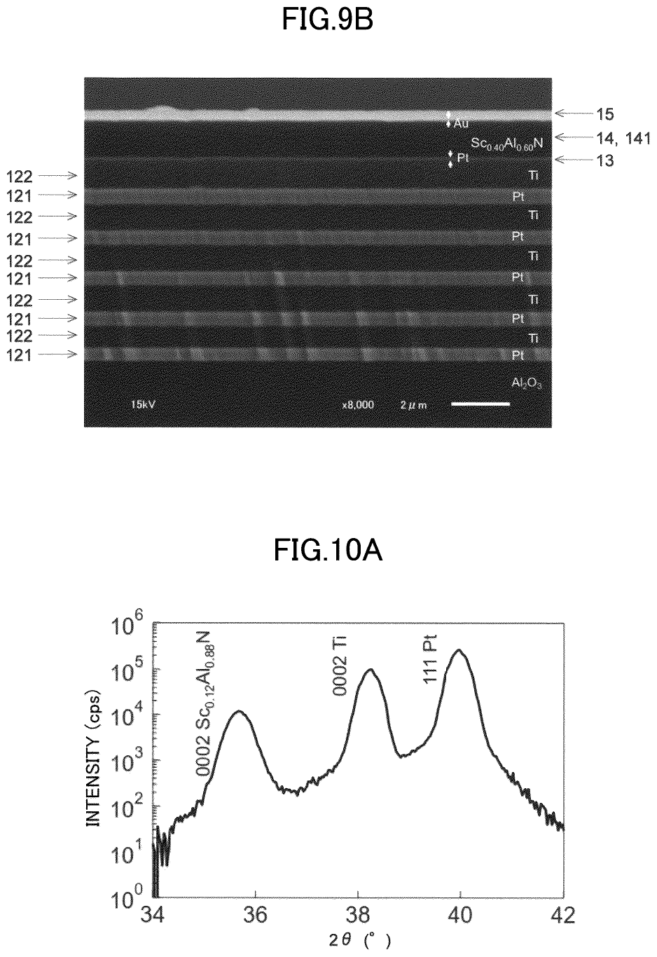

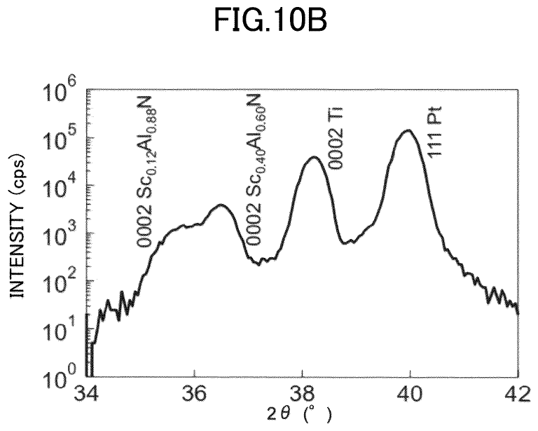

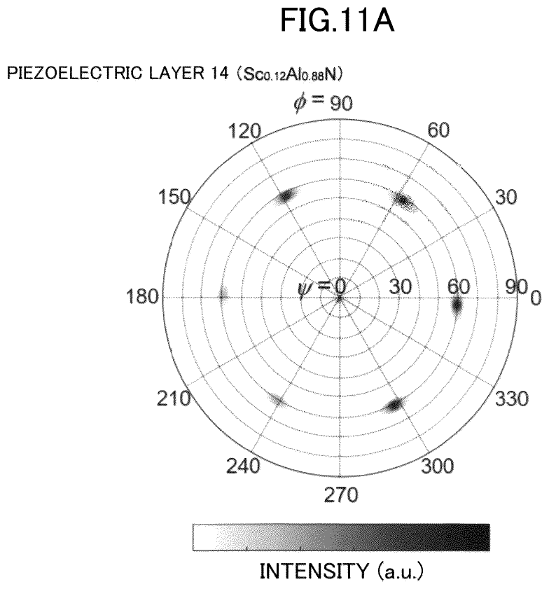

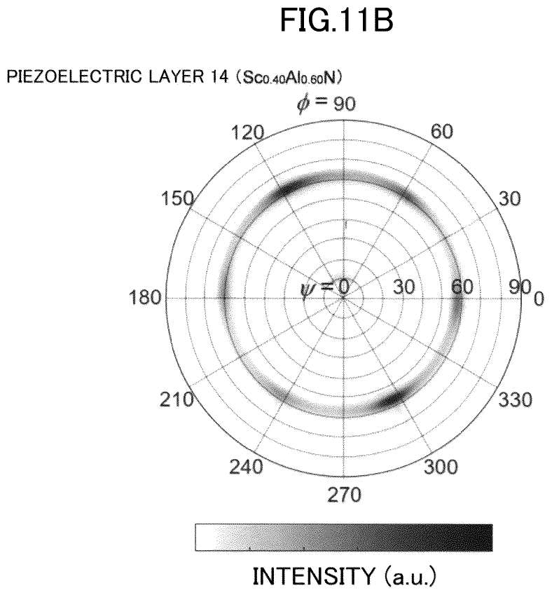

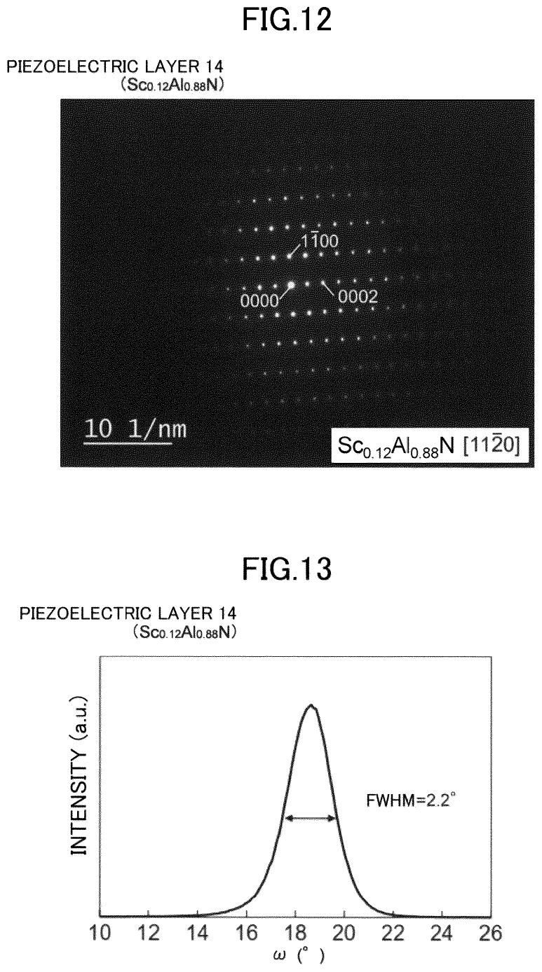

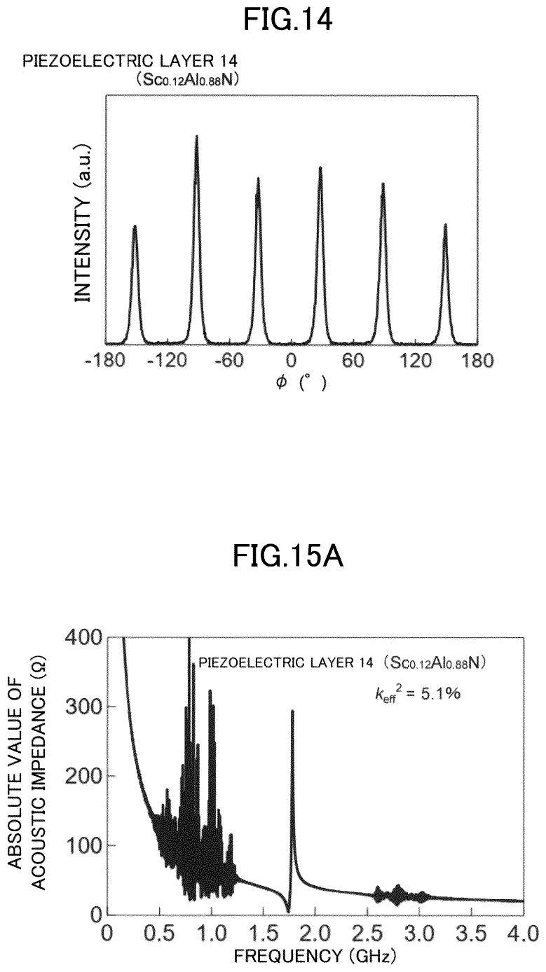

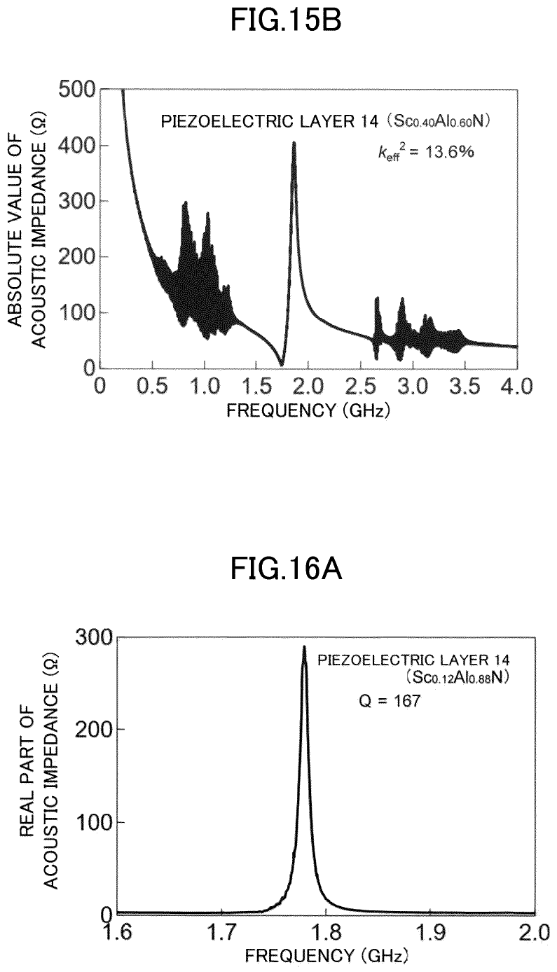

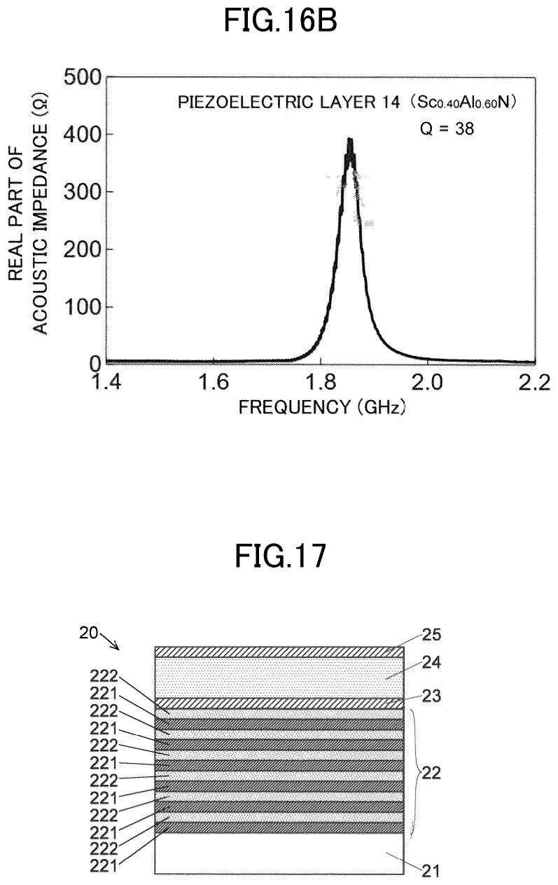

Among examples of the SMR-type BAW filter 10 manufactured by producing the piezoelectric layer 14 without heating with a heater, for an example of the piezoelectric layer 14 formed of Sc_{0.12}Al_{0.88}N, a SEM photograph of a vertical cross-section is presented in FIG. 9A, the measurement result of X-ray diffraction by a 2θ-ω scan is presented in FIG. 10A, a (10-11) pole figure of the piezoelectric layer 14 obtained by X-ray diffraction is presented in FIG. 11A, a measurement result of acoustic impedance is presented in FIG. 15A, and a determination result of the real part of the acoustic impedance is presented in FIG. 16A. Similarly, for an example of the piezoelectric layer 14 formed of Sc_{0.40}Al_{0.60}N, a SEM photograph of a vertical cross-section is presented in FIG. 9B, the result of a 2θ-ω scan is presented in FIG. 10B, a (10-11) pole figure of the piezoelectric layer 14 is presented in FIG. 11B, the measurement result of acoustic impedance is presented in FIG. 15B, and a determination result of the real part of the acoustic impedance is presented in FIG. 16B. Further, for the example of the piezoelectric layer 14 formed of Sc_{0.12}Al_{0.88}N, an electron diffraction image is presented in FIG. 12, the measurement result of X-ray diffraction by an ω scan is presented in FIG. 13, and the measurement result of X-ray diffraction by a φ scan on the (10-11) plane is presented in FIG. 14.

In the example in which the piezoelectric layer 14 formed of Sc_{0.12}Al_{0.88}N was produced without heating had the X-ray diffraction peak of the 2θ-ω scan, which was one order larger (FIG. 10A relative to FIG. 4C), the clearer spots having 6-fold rotational symmetry were observed in the (10-11) pole figure (FIG. 11A relative to FIG. 5E), and the clearer electron diffraction image was obtained (FIG. 12 relative to FIG. 6B), compared to the example in which the piezoelectric layer 14 having the same composition was produced with heating at 450° C. The above results indicate that orientation of crystals of the piezoelectric layer 14 formed of Sc_{0.12}Al_{0.88}N could be more desirably achieved when heating was not performed during production. Moreover, (although there is no data of an example in which production is performed while heating at 450° C.), in the example in which the piezoelectric layer 14 formed of Sc_{0.12}Al_{0.88}N was produced without heating, a sharp peak having a narrow line width was observed by the ω scan, and the clear 6-fold rotational symmetry was observed by the φ scan.

In the example in which the piezoelectric layer 14 formed of Sc_{0.40}Al_{0.60}N was produced without heating, particularly as presented in the (10-11) pole figure of FIG. 11B, it was demonstrated that the piezoelectric layer 14 oriented to follow the 6-fold rotational symmetry of the crystals of the substrate 11 and the acoustic Bragg reflector 12 was obtained. Such orientation could not be obtained when the piezoelectric layer 14 formed of Sc_{0.40}Al_{0.60}N was produced while heating.

The above results indicate that the piezoelectric layer 14 formed of scandium aluminum nitride was preferably produced without heating with a heater. This is considered due to that it is inevitable for scandium as a raw material to include a trace of oxygen atoms as impurities, and the oxygen atoms remain in the raw material when the piezoelectric layer 14 is produced without heating with a heater, whereas the oxygen atoms in the raw materials are released when the piezoelectric layer 14 is produced with heating.

For the above two examples, the acoustic impedance was measured (FIG. 15A and FIG. 15B). Based on the results of the acoustic impedance, keff² that was a square value of an effective value keff of the electromechanical coupling constant was determined. As a result, keff² was 5.1% in the example in which the piezoelectric layer 14 was formed of Sc_{0.12}Al_{0.88}N, and keff² was 13.6% in the example in which the piezoelectric layer 14 was formed of Sc_{0.40}Al_{0.60}N. The above results indicate that keff² increases due to an increase in an amount of Sc having a higher atomic mass than Al, thereby enhancing the acoustic characteristics.

As a Q value was estimated from the real part of the acoustic impedance (FIG. 16A and FIG. 16B), the Q value was 167 in the example in which the piezoelectric layer 14 was formed of Sc_{0.12}Al_{0.88}N, and the Q value was 38 in the example in which the piezoelectric layer 14 was formed of Sc_{0.40}Al_{0.60}N. The above results indicate that a ratio c/a of the c-axis length to the a-axis length is reduced by increasing the Sc content so that keff² was increased, and therefore piezoelectric characteristics are enhanced.

Note that the boundary between the buffer layer 141 formed of Sc_{0.12}Al_{0.88}N and the piezoelectric layer 14 formed of Sc_{0.40}Al_{0.60}N is not seen in the SEM photograph of FIG. 9B. This is because the buffer layer 141 and the piezoelectric layer 14 have substantially the same structure except for the atomic ratio of scandium to aluminum, and therefore it is difficult to distinguish the buffer layer 141 and the piezoelectric layer 14 in the SEM photograph.

### (4) Configuration and Method for Manufacturing SMR-Type BAW Filter of Second Embodiment

FIG. 17 illustrates a configuration of an SMR-type BAW filter 20 that is one embodiment (second embodiment) of a second SMR-type BAW filter. The SMR-type BAW filter 20 has a structure in which a substrate 21, an acoustic Bragg reflector 22, a first electrode layer 23, a piezoelectric layer 24, and a second electrode layer 25 are stacked in this order. Among the above constituent components, the substrate 21, the first electrode layer 23, the piezoelectric layer 24, and the second electrode layer 25 are the same as the substrate 11, the first electrode layer 13, the piezoelectric layer 14, and the second electrode layer 15 in the SMR-type BAW filter 10 of the first embodiment, respectively.

The acoustic Bragg reflector 22 has a structure in which first acoustic impedance layers 221 each formed of a metal and second acoustic impedance layers 222 each formed of a ceramic are stacked alternately one by one. In FIG. 17, six first acoustic impedance layers 221 and six second acoustic impedance layer 222 are disposed, but the number of layers are not limited to 6 layers each, as long as two layers or more are provided for each. Both the first acoustic impedance layers 221 and the second acoustic impedance layers 222 are in an oriented polycrystalline or monocrystalline form produced by epitaxy.

Examples of the metal used as a material of the first acoustic impedance layers 221 include platinum, titanium, and the like. Examples of the ceramic used as a material of the second acoustic impedance layers 222 include zinc oxide, magnesium zinc oxide, aluminum nitride, scandium aluminum nitride, and the like. A combination of the material of the first acoustic impedance layers 221 and the material of the second acoustic impedance layers 222 is selected so that acoustic impedances of both materials are different from each other.

A method for manufacturing the SMR-type BAW filter 20 of the second embodiment is the same as the method for manufacturing the SMR-type BAW filter 10 of the first embodiment, except that a ceramic (instead of the metal in the first embodiment) is allowed to epitaxially grow when each second acoustic impedance layer 222 is produced. An epitaxial growth method of the ceramic of the second acoustic impedance layer 222 is the same as the epitaxial growth method for the ceramic of the piezoelectric layers 14 and 24.

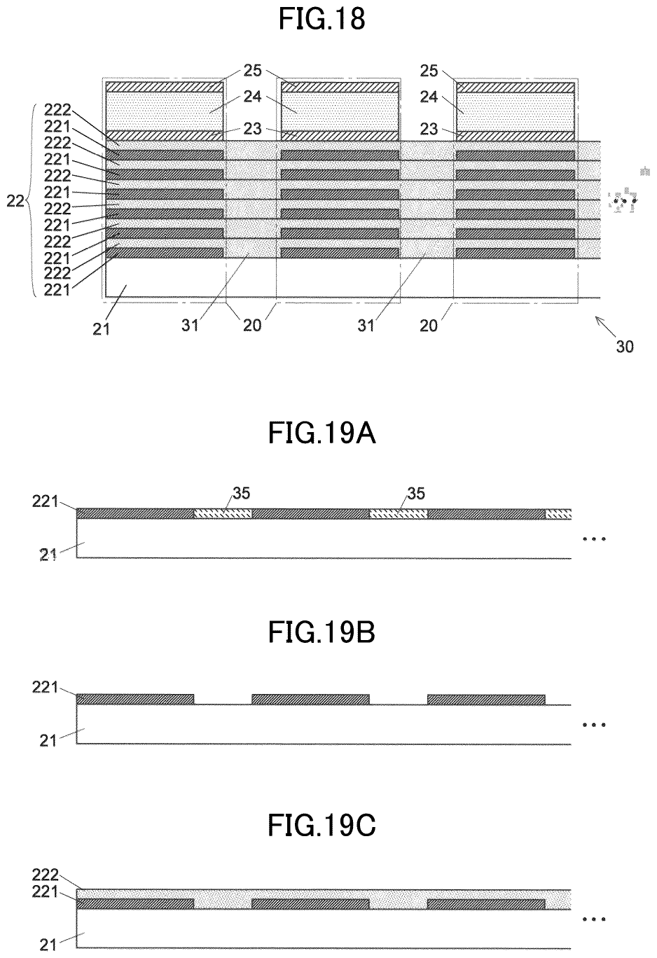

The SMR-type BAW filter of the second embodiment can be configured, for example, as an integrated device (simply referred to as a “device” hereinafter) 30 in which two or more of the SMR-type BAW filters are combined as illustrated in FIG. 18. In the example of FIG. 18, multiple SMR-type BAW filter 20 are disposed at different positions on one sheet of a substrate 21 by forming an acoustic Bragg reflector 22, in which first acoustic impedance layers 221 and second acoustic impedance layers 222 are alternately stacked, a first electrode layer 23, a piezoelectric layer 24, and a second electrode layer 25 in this order. Between the adjacent SMR-type BAW filters 20, a connecting member 31 formed of the same ceramic as the second acoustic impedance layer 222 is disposed between the adjacent acoustic Bragg reflectors 22. Each second acoustic impedance layer 222 and the connecting member 31 are formed integrally. Note that the SMR-type BAW filters 20 may be aligned one dimensionally or two dimensionally.

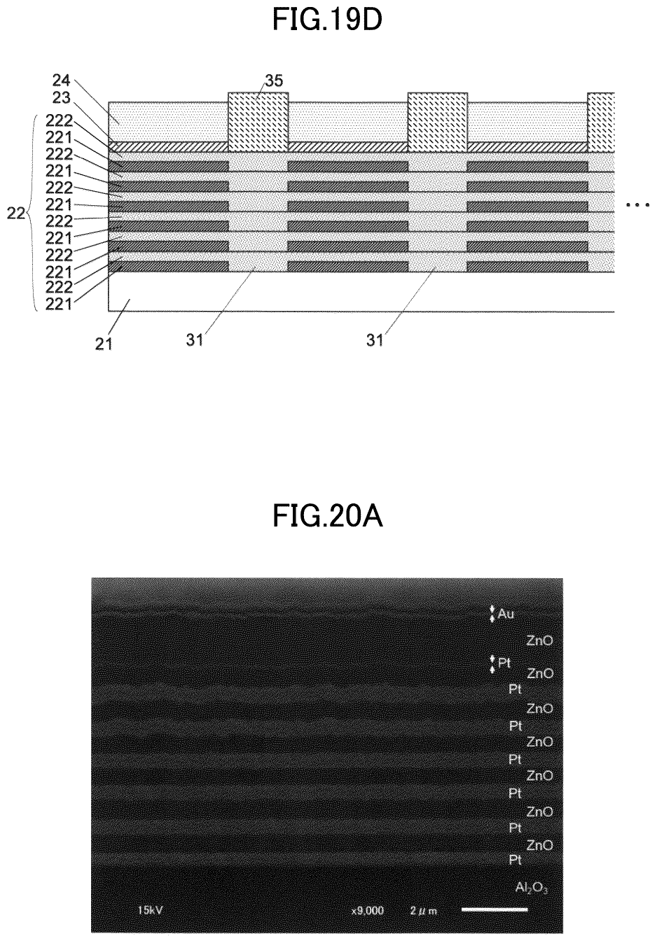

The device 30 can be produced by the following method. First, a mask 35 is formed in a location of a substrate 21 where a connecting member 31 is disposed, a first acoustic impedance layer 221 formed of a metal is formed on the substrate 21 by epitaxy (FIG. 19A). Next, the mask 35 is removed (FIG. 19B), and a second acoustic impedance layer 222 and a connecting member 31, both of which are formed of a ceramic, are simultaneously formed by epitaxy (FIG. 19C). The process up to this point is repeatedly performed to form an acoustic Bragg reflector 22. Thereafter, a mask 35 is formed on a top surface of the connecting member 31, a first electrode layer 23 and a piezoelectric layer 24 are formed in this order on the acoustic Bragg reflector 22 by epitaxy (FIG. 19D). Finally, a second electrode layer 25 is formed on the piezoelectric layer 24 (in this case, epitaxy may be used, or any other method may be used), thereby completing a device 30. According to the above method, each second acoustic impedance layer 222 and the connecting member 31 are simultaneously formed so that the production process can be simplified.

### (5) Measurement Results of MR-Type BAW Filter of Second Embodiment

Next, the results of various measurements performed on the actually produced SMR-type BAW filters 20 of the second embodiment will be described. The produced SMR-type BAW filters 20 were three types of SMR-type BAW filters, all of which included a first acoustic impedance layer 221 formed of platinum that was a metal, a second acoustic impedance layer 222 formed of zinc oxide that was a ceramic, and which included a piezoelectric layer 24 formed of zinc oxide (ZnO), a piezoelectric layer 24 formed of magnesium zinc oxide (Mg_{0.3}Zn_{0.7}O), and a piezoelectric layer 24 formed of scandium aluminum nitride (Sc_{0.2}Al_{0.8}N), respectively.

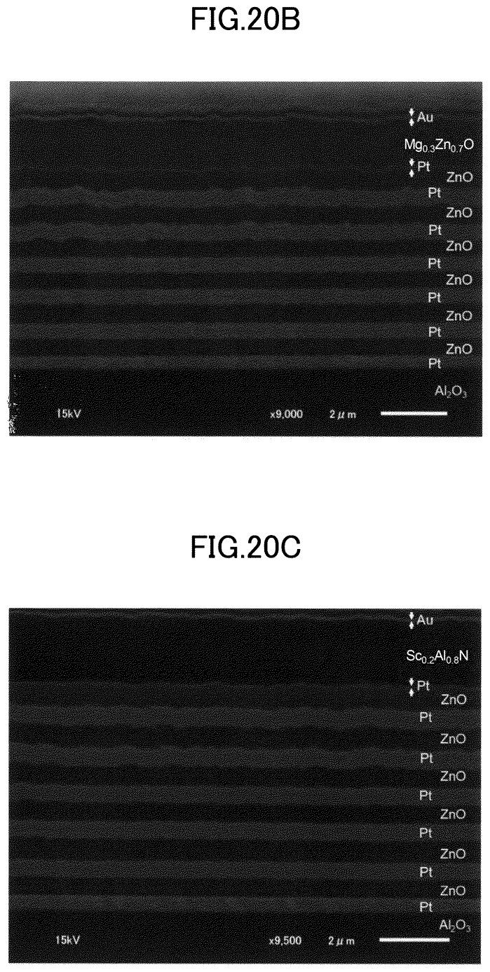

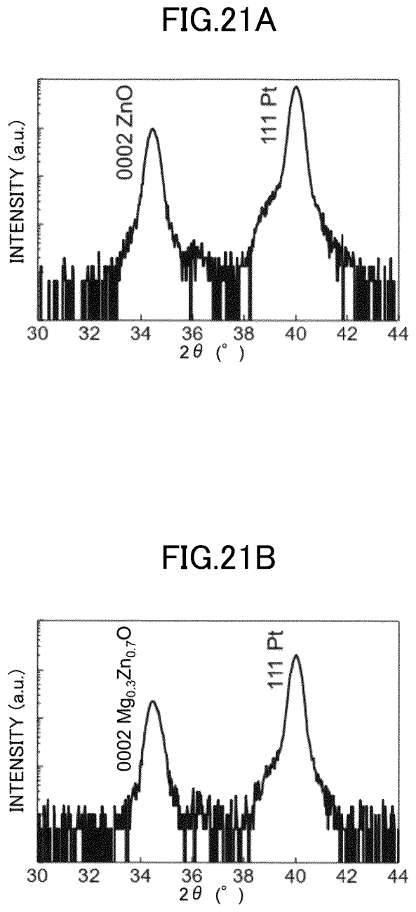

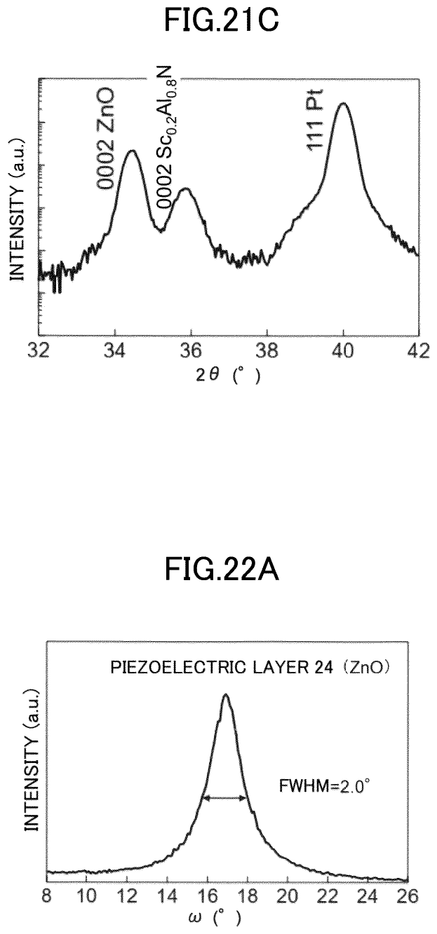

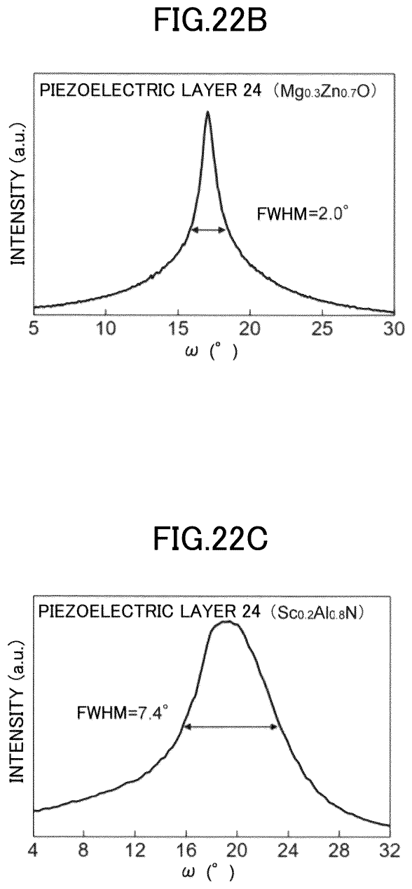

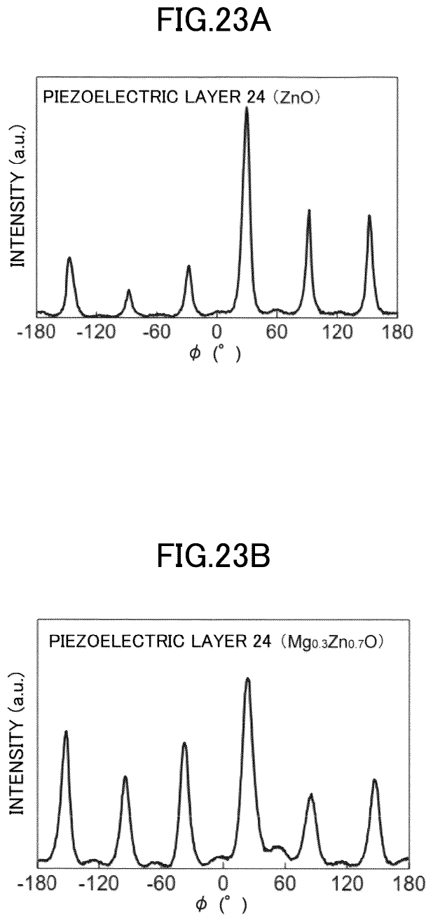

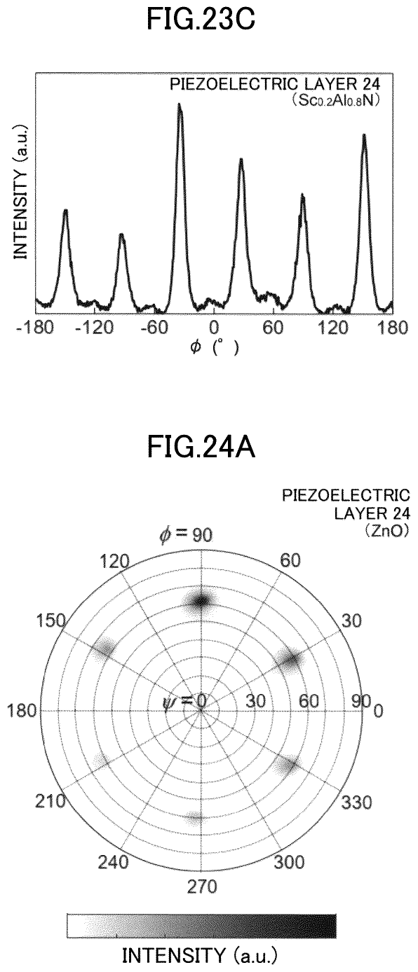

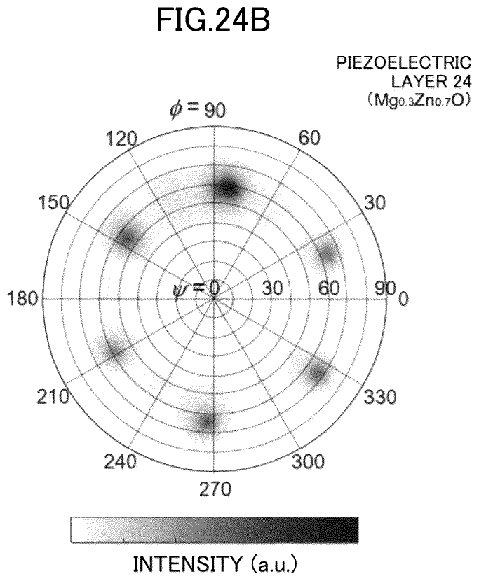

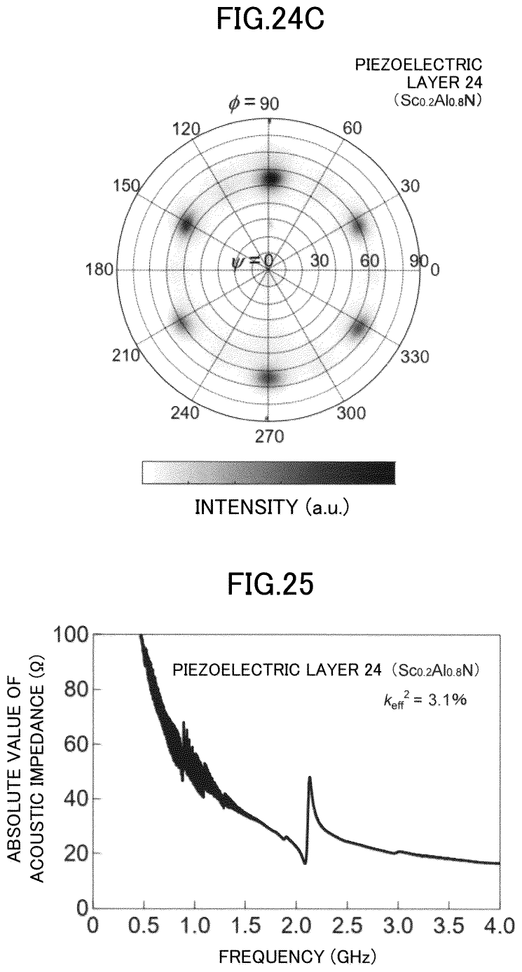

For the above three examples, SEM photographs of vertical cross-sections are presented in FIGS. 20A to 20C, the measurement results of X-ray diffraction by a 2θ-ω scan are presented in FIGS. 21A to 21C, the results of an ω scan are presented in FIGS. 22A to 22C, the results of a φ scan on the (10-11) plane are presented in FIGS. 23A to 23C, and the (10-11) pole figures of the piezoelectric layers 24 obtained by X-ray diffraction are presented in FIGS. 24A to 24C. For numbering of the figures, among the above three examples, a suffix “A” is assigned to the piezoelectric layer 24 formed of ZnO (for example, FIG. 20A), a suffix “B” is assigned to the piezoelectric layer 24 formed of Mg_{0.3}Zn_{0.7}O (for example, FIG. 20B), and a suffix “C” is assigned to the piezoelectric layer 24 formed of Sc_{0.2}Al_{0.8}N (for example, FIG. 20C). It was confirmed in all of the three examples that the expected crystals (ZnO, Mg_{0.3}Zn_{0.7}O, or Sc_{0.2}Al_{0.8}N) were formed in the piezoelectric layer 24 (FIGS. 21A to 21C), and were oriented to have 6-fold rotational symmetry (FIGS. 23A to 23C and FIGS. 24A to 24C). Moreover, the piezoelectric layer 24 formed of ZnO and the piezoelectric layer 24 formed of Mg_{0.3}Zn_{0.7}O had the smaller full width at half maximum (FWHM) of the profile obtained by the ω scan (FIGS. 22A to 22C) and more desirable crystalline characteristics than the piezoelectric layer 24 formed of Sc_{0.2}Al_{0.8}N.

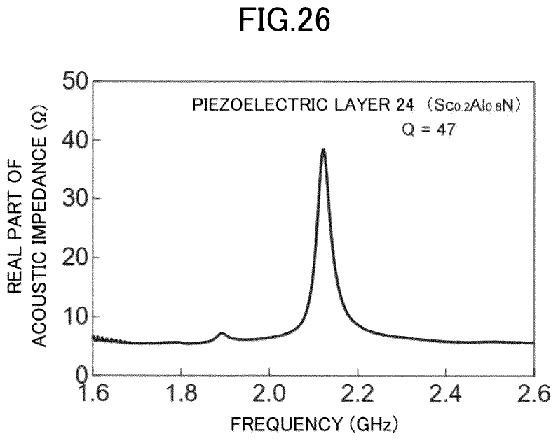

The acoustic impedance (FIG. 25) and the real part of the acoustic impedance (FIG. 26) of the SMR-type BAW filter 20 including the piezoelectric layer 24 formed of Sc_{0.2}Al_{0.8}N were measured to determine a value of keff² and a Q value. As result, keff² was 3.1%, and Q was 47.

The embodiments of the SMR-type BAW filter and the method for manufacturing the SMR-type BAW filter according to the present invention have been described above with modification examples. However, the present invention is not limited to the above embodiments and modification examples, and further modification is possible within the scope of the gist of the present invention.

### Embodiments

It is clear for a person skilled in the art that the above-described exemplary embodiments are concrete examples of the following embodiments.
(First Clause) An SMR-type BAW filter according to one embodiment of the present invention includes:
a) an acoustic Bragg reflector including first acoustic impedance layers and second acoustic impedance layers stacked alternately one by one,
   each first acoustic impedance layer and each second acoustic impedance layer being formed of a polycrystalline or monocrystalline metal oriented in a predetermined direction, and
   acoustic impedance of each first acoustic impedance layer and acoustic impedance of each second acoustic impedance layer being different from each other; and
b) a piezoelectric layer disposed on the acoustic Bragg reflector,
   the piezoelectric layer being formed of a polycrystalline or monocrystalline piezoelectric material oriented in a predetermined direction, and
   a crystal lattice of the polycrystalline or monocrystalline piezoelectric material being matched with a crystal lattice of the polycrystalline or monocrystalline metal of one layer among the first acoustic impedance layers and the second acoustic impedance layers, which is positioned in a vicinity of the piezoelectric layer.
(Second Clause) The second SMR-type BAW filter of Second Clause is directed to the SMR-type BAW filter according to First Clause in which an index value of a thermal expansion coefficient ratio is in a range of 1.0 to 1.1, where the index value of the thermal expansion coefficient ratio is a value obtained by dividing a higher value by a lower value between a value of a coefficient of thermal expansion of each first acoustic impedance layer and a value of a coefficient of thermal expansion of each second acoustic impedance layer.
(Third Clause) The SMR-type BAW filter of Third Clause is directed to the SMR-type BAW filter according to First Clause or Second Clause, in which an index value of an acoustic impedance ratio is 3 or greater, where the index value of the acoustic impedance ratio is a value obtained by dividing a higher value by a lower value between a value of the acoustic impedance of each first acoustic impedance layer and a value of the acoustic impedance of each second acoustic impedance layer.
(Fourth Clause) The SMR-type BAW filter of Fourth Clause is directed to the SMR-type BAW filter according to Second Clause or Third Clause, in which either each first acoustic impedance layer or each second acoustic impedance layer is formed of platinum, and the other is formed of titanium.
(Fifth Clause) An SMR-type BAW filter according to another embodiment of the present invention includes:
a) an acoustic Bragg reflector including first acoustic impedance layers and second acoustic impedance layers stacked alternately one by one,
   each first acoustic impedance layer being formed of a polycrystalline or monocrystalline metal oriented in a predetermined direction, and
   each second acoustic impedance layer being formed of a polycrystalline or monocrystalline ceramic oriented in a predetermined direction, and having acoustic impedance different from acoustic impedance of each first acoustic impedance layer; and
b) a piezoelectric layer disposed on the acoustic Bragg reflector,
   the piezoelectric layer being formed of a polycrystalline or monocrystalline piezoelectric material oriented in a predetermined direction, and
   a crystal lattice of the polycrystalline or monocrystalline piezoelectric material being matched with a crystal lattice of a polycrystalline or monocrystalline layer among the first acoustic impedance layers and the second acoustic impedance layer, which is positioned in a vicinity of the piezoelectric layer.
(Sixth Clause) An SMR-type BAW filter of Sixth Clause includes:
two of the SMR-type BAW filters according to Fifth Clause arranged to be apart from each other in a direction parallel to the first acoustic impedance layers and the second acoustic impedance layers; and
a connecting member formed of a ceramic, via which the acoustic Bragg reflectors in the two of the SMR-type BAW filters are coupled to each other.
(Seventh Clause) A method for manufacturing an SMR-type BAW filter of Seventh Clause includes:
a substrate preparation step of preparing a monocrystalline substrate having a predetermined crystallographic plane at a surface of the monocrystalline substrate;
an acoustic Bragg reflector production step of forming first acoustic impedance layers and second acoustic impedance layers alternately one by one on the surface of the monocrystalline substrate by epitaxy to produce an acoustic Bragg reflector,
   each first acoustic impedance layer and each second acoustic impedance layer being formed of a metal having a crystal lattice matched with a crystal lattice of the monocrystalline substrate, and
   acoustic impedance of each first acoustic impedance layer and acoustic impedance of each second acoustic impedance layer being different from each other; and
a piezoelectric layer production step of producing a piezoelectric layer on the acoustic Bragg reflector by epitaxy,
   the piezoelectric layer being formed of a piezoelectric material having a crystal lattice matched with a crystal lattice of the metal of an uppermost layer among the first acoustic impedance layers and the second acoustic impedance layers.
(Eighth Clause) A method for manufacturing an SMR-type BAW filter of Eighth Clause includes:
a substrate preparation step of preparing a monocrystalline substrate having a predetermined crystallographic plane at a surface of the monocrystalline substrate;
an acoustic Bragg reflector production step of forming first acoustic impedance layers and second acoustic impedance layers alternately one by one on the surface of the monocrystalline substrate by epitaxy to produce an acoustic Bragg reflector,
   each first acoustic impedance layer being formed of a polycrystalline or monocrystalline metal oriented in a predetermined direction,
   each second acoustic impedance layer being formed of a polycrystalline or monocrystalline ceramic oriented in a predetermined direction, and having acoustic impedance different from acoustic impedance of each first acoustic impedance layer; and
a piezoelectric layer production step of producing a piezoelectric layer on the acoustic Bragg reflector by epitaxy,
   the piezoelectric layer being formed of a piezoelectric material having a crystal lattice matched with a crystal lattice of an uppermost layer among the first acoustic impedance layers and the second acoustic impedance layers.
(Ninth Clause) The method for manufacturing the SMR-type BAW filter of Ninth Clause is directed to the method for producing the SMR-type BAW filter according to Eighth Clause, in which the acoustic Bragg reflector production step includes:
when the first acoustic impedance layers and the second acoustic impedance layer are formed, producing two acoustic Bragg reflectors being apart from each other in a direction parallel to the first acoustic impedance layers and the second acoustic impedance layers; and
at the same time as the formation of each second acoustic impedance layer, allowing the polycrystalline or monocrystalline ceramic to grow between two of the second acoustic impedance layers and between two of the first acoustic impedance layers immediately below the two of the second acoustic impedance layers.

Both the SMR-type BAW filter according to First Clause and the SMR-type BAW filter according to Fifth Clause include:
a) an acoustic Bragg reflector including first acoustic impedance layers and second acoustic impedance layers stacked alternately one by one,
   each first acoustic impedance layer being formed of a polycrystalline or monocrystalline metal oriented in a predetermined direction,
   each second acoustic impedance layer being formed of a polycrystalline or monocrystalline metal or ceramic oriented in a predetermined direction, having acoustic impedance different from acoustic impedance of each first acoustic impedance layer; and
b) a piezoelectric layer disposed on the acoustic Bragg reflector,
   the piezoelectric layer being formed of a polycrystalline or monocrystalline piezoelectric material oriented in a predetermined direction, and
   a crystal lattice of the polycrystalline or monocrystalline piezoelectric material being matched with a crystal lattice of a polycrystalline or monocrystalline layer among the first acoustic impedance layers and the second acoustic impedance layer, which is positioned in a vicinity of the piezoelectric layer.

The method for manufacturing an SMR-type BAW filter according to Seventh Clause and the method for manufacturing an SMR-type BAW filter according to Eighth Clause both include:
a substrate preparation step of preparing a monocrystalline substrate having a predetermined crystallographic plane at a surface of the monocrystalline substrate;
an acoustic Bragg reflector production step of forming first acoustic impedance layers and second acoustic impedance layers alternately one by one on the surface of the monocrystalline substrate by epitaxy to produce an acoustic Bragg reflector,
   each first acoustic impedance layer being formed of a polycrystalline or monocrystalline metal oriented in a predetermined direction,
   each second acoustic impedance layer being formed of a polycrystalline or monocrystalline metal or ceramic oriented in a predetermined direction, and having acoustic impedance different from acoustic impedance of each first acoustic impedance layer; and
a piezoelectric layer production step of producing a piezoelectric layer on the acoustic Bragg reflector by epitaxy,
   the piezoelectric layer being formed of a piezoelectric material having a crystal lattice matched with a crystal lattice of an uppermost layer among the first acoustic impedance layers and the second acoustic impedance layers.

The present application is based on and claims priority to Japanese Patent Application No. 2023-8867, filed in Japan Patent Office on Jan. 24, 2023, and Japanese Patent Application No. 2023-140222, filed in Japan Patent Office on Aug. 30, 2023, the entire contents of which are incorporated herein by reference.

### DESCRIPTION OF REFERENCE NUMERALS

10, 20: SMR-type BAW filter
11, 21: substrate
12, 22: acoustic Bragg reflector
121, 221: first acoustic impedance layer
122, 222: second acoustic impedance layer
13, 23: first electrode layer
14, 24: piezoelectric layer
141: buffer layer
15, 25: second electrode layer
30: integral device in which two or more SMR-type BAW filters are combined.
31: connecting member
35: mask

1. An SMR-type BAW filter, comprising:
a) an acoustic Bragg reflector including first acoustic impedance layers and second acoustic impedance layers stacked alternately one by one,
each first acoustic impedance layer and each second acoustic impedance layer being formed of a polycrystalline or monocrystalline metal oriented in a predetermined direction, and
acoustic impedance of each first acoustic impedance layer and acoustic impedance of each second acoustic impedance layer being different from each other; and
b) a piezoelectric layer disposed on the acoustic Bragg reflector,
the piezoelectric layer being formed of a polycrystalline or monocrystalline piezoelectric material oriented in a predetermined direction, and
a crystal lattice of the polycrystalline or monocrystalline piezoelectric material being matched with a crystal lattice of the polycrystalline or monocrystalline metal of one layer among the first acoustic impedance layers and the second acoustic impedance layers, which is positioned in a vicinity of the piezoelectric layer.

2. The SMR-type BAW filter according to claim 1,
wherein an index value of a thermal expansion coefficient ratio is in a range of 1.0 to 1.1, where the index value of the thermal expansion coefficient ratio is a value obtained by dividing a higher value by a lower value between a value of a coefficient of thermal expansion of each first acoustic impedance layer and a value of a coefficient of thermal expansion of each second acoustic impedance layer.

3. The SMR-type BAW filter according to claim 1,
wherein an index value of an acoustic impedance ratio is 3 or greater, where the index value of the acoustic impedance ratio is a value obtained by dividing a higher value by a lower value between a value of the acoustic impedance of each first acoustic impedance layer and a value of the acoustic impedance of each second acoustic impedance layer.

4. The SMR-type BAW filter according to claim 2,
wherein either each first acoustic impedance layer or each second acoustic impedance layer is formed of platinum, and the other is formed of titanium.

5. An SMR-type BAW filter, comprising:
a) an acoustic Bragg reflector including first acoustic impedance layers and second acoustic impedance layers stacked alternately one by one,
each first acoustic impedance layer being formed of a polycrystalline or monocrystalline metal oriented in a predetermined direction, and
each second acoustic impedance layer being formed of a polycrystalline or monocrystalline ceramic oriented in a predetermined direction, and having acoustic impedance different from acoustic impedance of each first acoustic impedance layer; and
b) a piezoelectric layer disposed on the acoustic Bragg reflector,
the piezoelectric layer being formed of a polycrystalline or monocrystalline piezoelectric material oriented in a predetermined direction, and
a crystal lattice of the polycrystalline or monocrystalline piezoelectric material being matched with a crystal lattice of a polycrystalline or monocrystalline layer among the first acoustic impedance layers and the second acoustic impedance layer, which is positioned in a vicinity of the piezoelectric layer.

6. An SMR-type BAW filter, comprising:
two of the SMR-type BAW filters according to claim 5 arranged to be apart from each other in a direction parallel to the first acoustic impedance layers and the second acoustic impedance layers; and
a connecting member formed of a ceramic, via which the acoustic Bragg reflectors in the two of the SMR-type BAW filters are coupled to each other.

7. A method for manufacturing the SMR-type BAW filter of claim 1, the method comprising:
preparing a monocrystalline substrate having a predetermined crystallographic plane at a surface of the monocrystalline substrate;
forming the first acoustic impedance layers and the second acoustic impedance layers alternately one by one on the surface of the monocrystalline substrate by epitaxy to produce the acoustic Bragg reflector,
each first acoustic impedance layer and each second acoustic impedance layer being formed of a metal having a crystal lattice matched with a crystal lattice of the monocrystalline substrate, and
acoustic impedance of each first acoustic impedance layer and acoustic impedance of each second acoustic impedance layer being different from each other; and
producing the piezoelectric layer on the acoustic Bragg reflector by epitaxy,
the piezoelectric layer being formed of the polycrystalline or monocrystalline piezoelectric material having a crystal lattice matched with a crystal lattice of the metal of an uppermost layer among the first acoustic impedance layers and the second acoustic impedance layers.

8. A method for manufacturing an SMR-type BAW filter, the method comprising:
preparing a monocrystalline substrate having a predetermined crystallographic plane at a surface of the monocrystalline substrate;
forming first acoustic impedance layers and second acoustic impedance layers alternately one by one on the surface of the monocrystalline substrate by epitaxy to produce an acoustic Bragg reflector,
each first acoustic impedance layer being formed of a polycrystalline or monocrystalline metal oriented in a predetermined direction,
each second acoustic impedance layer being formed of a polycrystalline or monocrystalline ceramic oriented in a predetermined direction, and having acoustic impedance different from acoustic impedance of each first acoustic impedance layer; and
producing a piezoelectric layer on the acoustic Bragg reflector by epitaxy,
the piezoelectric layer being formed of a piezoelectric material having a crystal lattice matched with a crystal lattice of an uppermost layer among the first acoustic impedance layers and the second acoustic impedance layers.

9. The method for manufacturing the SMR-type BAW filter according to claim 8,
wherein the forming includes:
when the first acoustic impedance layers and the second acoustic impedance layer are formed, producing two acoustic Bragg reflectors being apart from each other in a direction parallel to the first acoustic impedance layers and the second acoustic impedance layers; and
at the same time as the formation of each second acoustic impedance layer, allowing the polycrystalline or monocrystalline ceramic to grow between two of the second acoustic impedance layers and between two of the first acoustic impedance layers immediately below the two of the second acoustic impedance layers.
